(19) United States
(12) Patent Application Publication
(10) Pub. No.: US 2026/0365881 A1
(43) Pub. Date: Nov. 19, 2026

(54) METHOD FOR MANUFACTURING ELECTRONIC APPARATUS AND ELECTRONIC APPARATUS

(71) Applicant: Samsung Display Co., Ltd., Yongin-si (KR)

(72) Inventor: Katsuhiro YAMAMOTO, Yokohama-shi (JP)

(21) Appl. No.: 19/653,945

(22) Filed: Apr. 21, 2026

(30) Foreign Application Priority Data
May 15, 2025 (JP) 2025-081850

(51) Int. Cl. C09J 5/02; H05K 5/03

(52) U.S. Cl. CPC C09J 5/02; H05K 5/03; C09J 2400/146

(57) ABSTRACT

A method for manufacturing an electronic apparatus, includes preparing a substrate, in which a first region and a second region around (e.g., surrounding) the first region are defined, and forming an adhesive member on the substrate, in which the forming of the adhesive member includes applying a first resin composition to the second region of the substrate, curing the first resin composition by irradiating first light, applying a second resin composition on a portion or an entirety of the cured first resin composition and on the first region of the substrate, curing the second resin composition by irradiating second light, and applying the first resin composition, multiple times. The first resin composition and the second resin composition include a same resin composition, and its shear viscosity measured in a JIS Z 8803 scheme at a temperature ranging from 20 °C to 30 °C ranges from 10 mPa·s to 20 mPa·s.

### CROSS-REFERENCE TO RELATED APPLICATION

The present application claims priority to and the benefit of Japanese Patent Application No 2025-081850, filed on May 15, 2025, in the Japan Patent Office, the entire disclosure of which is incorporated herein by reference.

### BACKGROUND

### 1. Field

One or more embodiments of the present disclosure relate to a method for manufacturing an electronic apparatus and the electronic apparatus.

### 2. Description of Related Art

Various types of display devices have been developed for use in multimedia products such as televisions, mobile phones, tablet computers, navigation systems, and/or game consoles. These display devices may include various components, with one or more adhesive members interposed between the components. The adhesive member may be formed utilizing a resin composition. In such display devices, the adhesive member is required or desired to bond the components of the display device reliably without degrading display quality.

### SUMMARY

One or more aspects of embodiments of the present disclosure are directed toward a method for manufacturing an adhesive member which has a higher elastic modulus after cured and is capable of preventing, protecting, or reducing a terminal end portion from being delaminated, and a method for manufacturing an electronic apparatus including the adhesive member.

One or more aspects of embodiments of the present disclosure are directed toward an electronic apparatus including an adhesive member that has a higher elastic modulus.

Additional aspects will be set forth in part in the description which follows and, in part, will be apparent from the description, or may be learned by practice of the presented embodiments.

According to one or more embodiments of the present disclosure, a method for manufacturing an electronic apparatus includes preparing a substrate, in which a first region and a second region around (e.g., surrounding) the first region are defined, and forming an adhesive member on the substrate, in which the forming of the adhesive member includes applying a first resin composition to the second region of the substrate, curing the first resin composition by irradiating first light, applying a second resin composition on a portion or an entirety (e.g., entire portion) of the cured first resin composition and on the first region of the substrate, and curing the second resin composition by irradiating second light, wherein the applying of the first resin composition is performed multiple times, wherein the first resin composition and the second resin composition include a same resin composition, wherein the resin composition is photo-cured under a condition, in which an accumulated light amount of UV light in an atmosphere (e.g., in air) is in a range of about 4,000 mJ/cm² to about 8,000 mJ/cm², a 180° peel strength, which is measured on a glass substrate at about 25 °C, is in a range of about 2 kgf/25 mm to about 5 kgf/25 mm, a 180° peel strength, which is measured on a glass substrate at about 60 °C, is in a range of about 0.5 kgf/25 mm to about 4 kgf/25 mm, and shear viscosity, which is measured in a JIS Z 8803 scheme at a temperature in a range of about 20 °C to about 30 °C, is in a range of about 10 mPa·s to about 20 mPa·s in each of the first resin composition and the second resin composition (e.g., shear viscosity of the resin composition, which is measured under JIS Z 8803 at a temperature in a range of about 20 °C to about 30 °C, is in a range of about 10 mPa·s to about 20 mPa·s).

A curing rate of the second resin composition may be in a range of about 50% to about 85% as calculated by Equation 1, after the second resin composition is cured.

Curing rate (%)=(cured PI₈₁₀/cured PI₁₇₃₀)/(uncured PI₈₁₀/uncured PI₁₇₃₀)×100 Equation 1

In Equation 1, PI₈₁₀ represents a peak intensity of about 810 cm⁻¹ measured by Fourier Transform Infrared Spectroscopy (FT-IR), and PI₁₇₃₀ represents a peak intensity of about 1730 cm⁻¹ measured by the FT-IR. The resin composition may be applied in an inkjet printing scheme (e.g., an inkjet printing process).

The resin composition may have storage modulus in a range of about 0.05 MPa to about 0.10 MPa, when the storage modulus is measured at about 25 °C, after performing a photo-curing process under a condition in which an accumulated light amount of UV light in an atmosphere (e.g., in air) is in a range of about 4,000 mJ/cm² to about 6,000 m J/cm².

The resin composition may have storage modulus in a range of about 0.05 MPa to about 0.18 MPa, when the storage modulus is measured at about 60 °C, after performing a photo-curing process under a condition in which an accumulated light amount of UV light in an atmosphere (e.g., in air) is in a range of about 4,000 mJ/cm² to about 6,000 mJ/cm².

In one or more embodiments, the applying of the first resin composition may be performed n times (2≤n≤5; n is an integer), an outer peripheral portion of the first resin composition applied at an n-th phase may be overlapped with an outer peripheral portion of the first resin composition applied in an (n−1)-th phase in a thickness direction, and a width of the first resin composition applied at the n-th phase may be smaller than a width of the first resin composition applied in the (n−1)-th phase.

An applying amount per unit area of the first resin composition applied at the n-th phase may be less than an applying amount per unit area of the first resin composition applied at the (n−1)-th phase.

An applying amount per unit area of the first resin composition applied at the n-th phase or at a first phase may be in a range of about 0.041 g/inch² to about 0.076 g/inch².

An applying amount per unit area of the second resin composition may be in a range of about 0.041 g/inch² to about 0.076 g/inch².

In one or more embodiments, each of the first light and the second light may include UVA. an illuminance of the UVA included in the first light may be in a range of about 400 mW/cm² to about 1,200 mW/cm². An accumulated light amount of the UVA may be in a range of about 300 mJ/cm² to about 700 mJ/cm².

In one or more embodiments, each of the first light and the second light may include UVV. The illuminance of the UVV included in the first light may be in a range of about 200 mW/cm² to about 600 mW/cm². The accumulated light amount of the UVV may be in range of about 120 mJ/cm² to about 150 mJ/cm².

In one or more embodiments, a width of the second region may be in a range of about 0.1 millimeters (mm) to about 2.0 mm.

According to one or more embodiments of the present disclosure, a method for manufacturing an electronic apparatus includes preparing a substrate, in which a first region and a second region around (e.g., surrounding) the first region are defined, and forming an adhesive member on the substrate, in which the forming of the adhesive member includes applying a first resin composition to the second region of the substrate, curing the first resin composition by irradiating first light, applying a second resin composition on a portion or an entirety (e.g., entire portion) of the cured first resin composition and on the first region of the substrate, and curing the second resin composition by irradiating second light, the applying of the first resin composition is performed n times (2≤n≤5; n is integer), an outer peripheral portion of the first resin composition applied at an n-th phase is overlapped with an outer peripheral portion of the first resin composition applied in an (n−1)-th phase, a width of the first resin composition applied at the n-th phase is smaller than a width of the first resin composition applied in the (n−1)-th phase, and shear viscosity, which is measured in a JIS Z 8803 scheme at a temperature in a range of about 20 °C to about 30 °C, is in a range of about 10 mPa·s to about 20 mPa·s in each of the first resin composition and the second resin composition.

The first resin composition and the second resin composition may include a same resin composition.

In the preparing for the substrate, the substrate may be seated on a stage, and the stage may have a temperature in a range of about 20 °C to about 30 °C.

The resin composition may be applied in an inkjet printing scheme (e.g., an inkjet printing process).

The adhesive member has a thickness in a range of about 50 micrometers (μm) to about 300 μm.

According to one or more embodiments of the present disclosure, an electronic apparatus includes a display module, a window on (e.g., arranged on) the display module, and an adhesive member interposed between the display module and the window, wherein the adhesive member includes a polymer derived from a resin composition, the resin composition is photo-cured under a condition, in which an accumulated light amount of UV light in an atmosphere (e.g., in air) is in a range of about 4,000 mJ/cm² to about 8,000 mJ/cm², a 180° peel strength, which is measured on a glass substrate at 25 °C, is in a range of about 2 kgf/25 mm to about 5 kgf/25 mm, and a 180° peel strength, which is measured on a glass substrate at about 60 °C, is in a range of about 0.5 kgf/25 mm to about 4 kgf/25 mm, and shear viscosity of the resin composition, which is measured in a JIS Z 8803 scheme at a temperature in a range of about 20 °C to about 30 °C, is in a range of about 10 mPa·s to about 20 mPa·s, a curing rate of the resin composition is in a range of about 50% to about 85% as calculated by Equation 1, after the resin composition is cured, and an edge gap between the display module and the adhesive member, or between the window and the adhesive member is at most about 100 μm.

Curing rate (%)=(cured PI₈₁₀/cured PI₁₇₃₀)/(uncured PI₈₁₀/uncured PI₁₇₃₀)×100 Equation 1

In Equation 1, PI₈₁₀ represents a peak intensity of about 810 cm⁻¹ measured by Fourier Transform Infrared Spectroscopy (FT-IR), and PI₁₇₃₀ represents a peak intensity of about 1730 cm⁻¹ measured by the FT-IR.

In one or more embodiments, the display module may include a display panel and an input sensing unit, and the adhesive member may be interposed between the input sensing unit arranged on the display panel and the window.

The electronic apparatus may further include at least one of a processor, a memory, or a power module.

According to one or more embodiments, the method and the electronic apparatus provide an adhesive member that is formed by inkjet-applying the same photo-curable resin composition in multiple passes to a peripheral second region (e.g., 2≤n≤5 with outer-edge overlap and a decreasing application width) and then applying the resin composition over at least a portion of the cured first application and a central first region, followed by UV curing (e.g., UVA and/or UVV) within the disclosed accumulated-light dosage ranges. The resin composition may exhibit a shear viscosity of 10 mPa·s to 20 mPa·s prior to cure, and after cure may provide 180° peel strengths of 2 kgf/25 mm to 5 kgf/25 mm at 25 °C and 0.5 kgf/25 mm to 4 kgf/25 mm at 60 °C, a curing rate of 50% to 85% as defined by Equation 1, and storage-modulus values within the disclosed ranges; in embodiments, the second region has a width of about 0.1 mm to about 2.0 mm, the stage temperature during application is about 20 °C to about 30 °C, and the adhesive member thickness is about 50 μm to about 300 μm. By coordinating these applications and curing conditions, the adhesive member may limit an edge gap to at most about 100 μm and thereby improve terminal-end adhesion and structural reliability when interposed between a display module and a window of an electronic apparatus.

### BRIEF DESCRIPTION OF THE DRAWINGS

The accompanying drawings are included to provide a further understanding of the present disclosure, and are incorporated in and constitute a part of this disclosure. The drawings illustrate embodiments of the present disclosure and, together with the description, serve to explain principles of the disclosure. The above and other objects and features of the present disclosure will become apparent from the following detailed descriptions of embodiments thereof with reference to the accompanying drawings.

FIG. 1 is a block diagram illustrating an electronic apparatus according to one or more embodiments of the present disclosure.

FIG. 2 illustrates schematic views of electronic apparatuses according to one or more embodiments of the present disclosure.

FIG. 3 is a perspective view illustrating an electronic apparatus according to one or more embodiments of the present disclosure;

FIG. 4 is an exploded perspective view illustrating a display device included in an electronic apparatus according to one or more embodiments of the present disclosure.

FIG. 5 is a cross-sectional view illustrating a part taken along the line I-I′ of FIG. 4 according to one or more embodiments of the present disclosure.

FIG. 6 is a cross-sectional view illustrating a portion of a display device according to one or more embodiments of the present disclosure.

FIG. 7 is a cross-sectional view illustrating a display device according to one or more embodiments of the present disclosure;

FIG. 8 is a cross-sectional view illustrating a display device according to one or more embodiments of the present disclosure;

FIG. 9A is a perspective view illustrating an electronic apparatus according to one or more embodiments of the present disclosure.

FIG. 9B is a perspective view illustrating an electronic apparatus according to one or more embodiments of the present disclosure.

FIG. 9C is a plan view illustrating an electronic apparatus according to one or more embodiments of the present disclosure.

FIG. 9D is a perspective view illustrating an electronic apparatus according to one or more embodiments of the present disclosure.

FIG. 10 is a flowchart illustrating a method for manufacturing an electronic apparatus according to one or more embodiments of the present disclosure.

FIG. 11 is a flowchart illustrating a manner for forming an adhesive member according to one or more embodiments of the present disclosure.

FIGS. 12A-12E are views schematically illustrating a manner for forming an adhesive member according to one or more embodiments of the present disclosure.

FIGS. 13A-13H are views schematically illustrating a manner for forming an adhesive member according to one or more embodiments of the present disclosure.

FIGS. 14A-14D illustrate images of cross-section of an adhesive member and a substrate according to Examples of the present disclosure.

FIGS. 15A-15D illustrate images of cross-section of an adhesive member and a substrate according to Comparative examples of the present disclosure.

### DETAILED DESCRIPTION

While aspects of the present disclosure may be practiced and implemented in one or more suitable modifications and alternative forms, certain embodiments thereof are shown by way of example in the drawings and will be described herein in more detail. It should be understood, however, that there is no intent to limit the present disclosure to the particular forms disclosed, but on the contrary, the present disclosure is to cover all modifications, equivalents, and alternatives falling within the spirit and scope of the present disclosure.

In the disclosure, the expression that a first component (or region, layer, or part) is “on”, “connected to”, or “coupled to” a second component refers to that the first component may be directly on, connected to, or coupled to the second component or refers to that a third component may be interposed therebetween. In contrast, “directly on” may refer to that there are no additional intervening elements or layers between the first component and the second component.

The same or like reference numeral will be assigned to the same or like component, and duplicative descriptions thereof may not be provided for conciseness. In addition, in drawings, proportions and dimensions (e.g., thicknesses) of components may be exaggerated or reduced to describe the technical features effectively. The term “and/or” or “or” or “/” may include any and all combinations of one or more of associated components.

Although the terms “first”, “second”, “third”, and/or the like may be used to describe one or more suitable components, the components should not be construed as being limited by the terms. The terms are only used to distinguish one component from another component. For example, without departing from the scope and spirit of the present disclosure, a first component may be referred to as a second component, and similarly, a second component may be referred to as a first component. The singular forms are intended to include the plural forms unless the context clearly indicates otherwise. For example, in the disclosure, the singular expressions “a”, “an,” and “the” are intended to include the plural forms as well, unless the context clearly indicates otherwise. Further, the use of “may” when describing embodiments of the present disclosure refers to “one or more embodiments of the present disclosure.”

In addition, the terms “under”, “at a lower portion”, “above”, “an upper portion”, and/or the like are used to describe the relationship between components illustrated in drawings. The terms are relative and will be described with reference to a direction indicated in the drawing.

It will be further understood that the terms “comprise(s)/comprising,” “include(s)/including,” or “has (have)/having” specify the presence of stated features, numbers, steps, operations, components, parts, or the combination thereof, but do not preclude the presence or addition of one or more other features, numbers, steps, operations, components, components, and/or the combination thereof. Additionally, the terms “comprise(s)/comprising,” “include(s)/including,” “have/has/having,” or other similar terms include or support the terms “consisting of” and “consisting essentially of,” indicating the presence of stated features, numbers, steps, operations, components, parts, or combinations thereof, without or essentially without the presence of other features, numbers, steps, operations, components, parts, or combinations thereof.

Unless defined otherwise, all terms (including technical terms and scientific terms) used in the disclosure have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, a method (e.g., a manner) for forming an adhesive member according to one or more embodiments of the present disclosure, a method for manufacturing an electronic apparatus according to one or more embodiments, and the electronic apparatus according to one or more embodiments will be described in more detail with reference to the drawings. According to one or more embodiments, an electronic apparatus may include a display device, and may further include a module or a device having other additional functions, in addition to the display device.

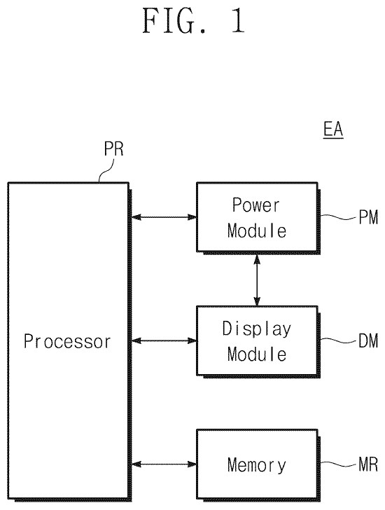

FIG. 1 is a block diagram illustrating of an electronic apparatus according to one or more embodiments. Referring to FIG. 1, an electronic apparatus EA according to one or more embodiments may include a display module DM, a processor PR, a memory MR, and a power module PM.

The processor PR may include at least one a central processing unit (CPU), an application processor (AP), a graphic processing unit (GPU), a communication processor (CP), an image signal processor (ISP), or a controller.

The memory MR may store data information necessary for operations of the processor PR and/or the display module DM. When the processor PR runs an application stored in the memory MR, an image data signal and/or an input control signal may be transmitted to the display module DM, and the display module DM may process the received signal and output the image information through a display screen.

The power module PM may include a power supply module, such as a power adaptor or a battery device, and a power converting module to convert the power received from the power supply module into power necessary for an operation of the electronic apparatus EA.

At least one of components of the electronic apparatus EA described above may be included in the display device according to one or more embodiments described herein. In one or more embodiments, some of individual modules functionally included in one module may be included in the display device, and others of the individual modules may be provided separately from the display device. For example, the display device may include the display module DM, and the processor PR, the memory MR, and the power module PM may be provided in the form of another device in the electronic apparatus EA instead of the display device.

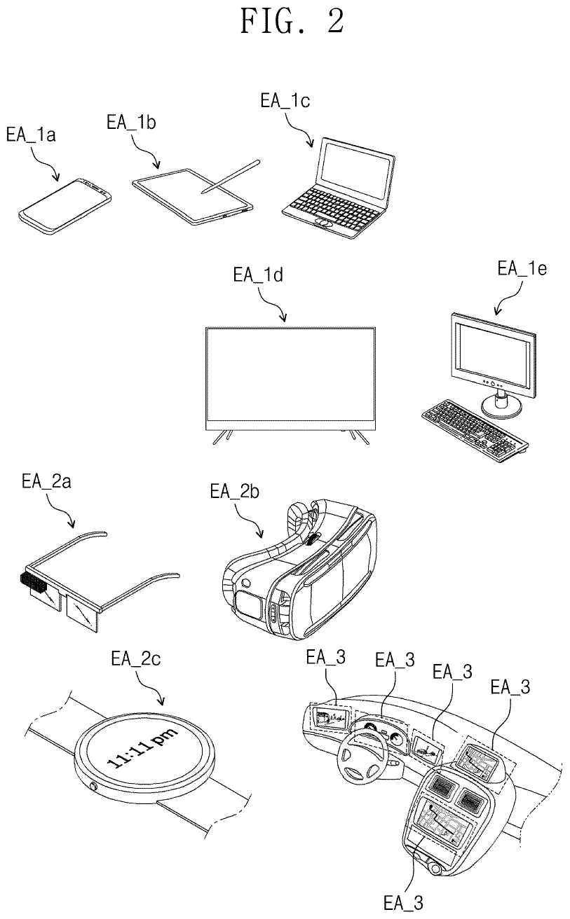

FIG. 2 illustrates schematic views of electronic apparatuses according to one or more embodiments of the present disclosure. Referring to FIG. 2, one or more suitable electronic apparatuses each employing the display device according to one or more embodiments may include wearable electronic apparatuses each including a display module such as smart glasses EA_2a, a head mounted display EA_2b, and a smart watch EA_2c, and electronic apparatuses EA_3 for a vehicle each including a display module such as a center information display (CID), which is arranged in an instrument panel, a center fascia, and a dashboard of a vehicle, and/or a room mirror display thereof, as well as electronic apparatuses for image display such as a smartphone EA_1a, a tablet PC EA_1b, a laptop computer EA_1c, a television (TV) EA_1d, and a desk monitor EA_1e.

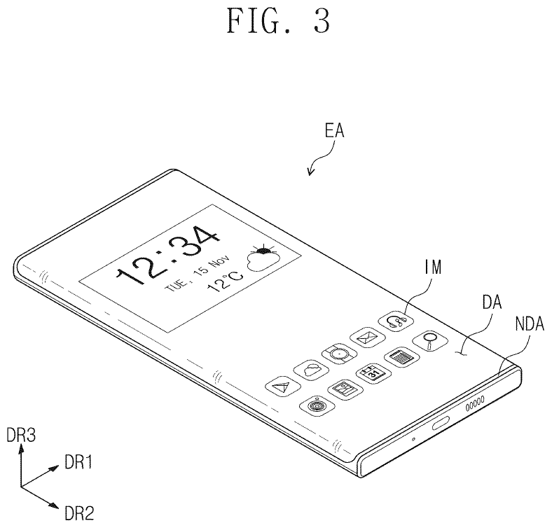

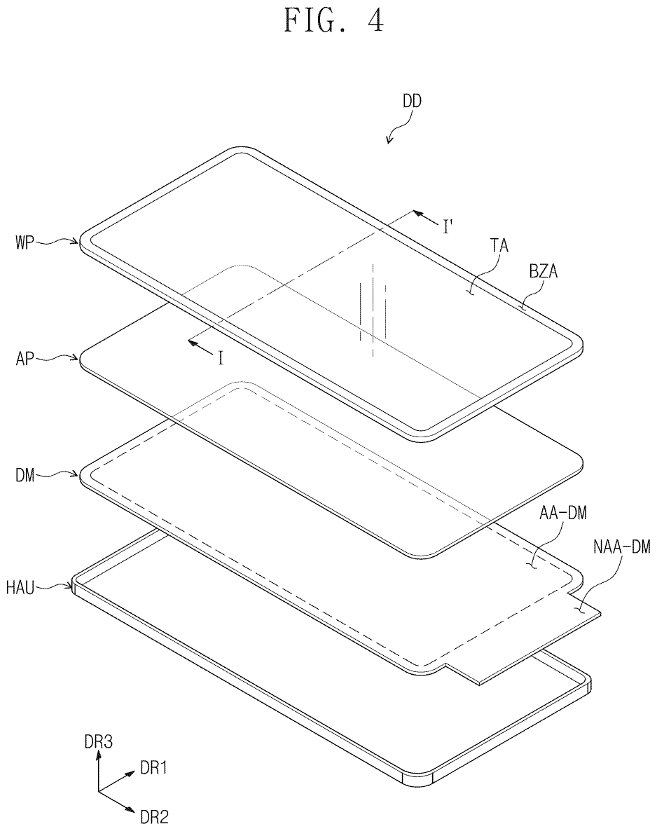

FIG. 3 is a perspective view illustrating an electronic apparatus according to one or more embodiments of the present disclosure; FIG. 4 is an exploded perspective view illustrating a display device included in an electronic apparatus according to one or more embodiments.

An electronic apparatus EA illustrated in FIG. 3 and according to one or more embodiments may be a device that is activated in response to an electrical signal. FIG. 3 illustrates that the electronic apparatus EA is a smartphone by way of example.

According to one or more embodiments, the electronic apparatus EA may display an image IM in a display region DA. The display region DA may include a plane defined by a first direction DR1 and a second direction DR2. In one or more embodiments, the display region DA may include a curved surface which is bent from at least one side of the plane defined by the first direction DR1 and the second direction DR2. FIG. 3 illustrates that the electronic apparatus EA according to one or more embodiments includes two curved surfaces respectively bent at opposite sides from the plane defined by the first direction DR1 and the second direction DR2. However, the shape of the display region DA is not limited thereto. For example, in one or more embodiments, the display region DA may include only the plane defined by the first direction DR1 and the second direction DR2, or may further include another two curved surfaces (e.g., four curved surfaces bent at four sides, respective, from the plane defined by the first direction DR1 and the second direction DR2).

The electronic apparatus EA according to one or more embodiments may be flexible. The “flexible” characteristic refers to a bendable characteristic, and a flexible structure may include all structures ranging from a fully folded structure to a structure bent by a level of several nanometers. For example, in one or more embodiments, the electronic apparatus EA may be a foldable device. In one or more embodiments, the electronic apparatus EA may be rigid.

A non-display region NDA may be a region adjacent to the display region DA. In one or more embodiments, the non-display region NDA may surround the display region DA. Accordingly, a shape of the display region DA may be defined substantially by the non-display region NDA. However, this is illustrated as an example. In one or more embodiments, the non-display region NDA may be arranged adjacent to only one side of the display region DA or may not be provided. The display region DA may be provided in one or more suitable shapes, but embodiments of the present disclosure are not limited thereto.

FIG. 3 and following drawings illustrate the first direction DR1, the second direction DR2, and a third direction DR3, and the directions indicated by the first direction DR1 to the third direction DR3 described in this disclosure may be relative concepts and may be converted into other directions. In addition, the directions indicated by the first to third directions DR1, DR2, and DR3 may also be referred to as the first to third directions and will be assigned with the same reference numerals. In this disclosure, the first direction DR1 and the second direction DR2 may be perpendicular to each other. The third direction DR3 may be a direction normal to the plane defined by the first direction DR1 and the second direction DR2.

A thickness direction of the electronic apparatus EA may be parallel to the third direction DR3 which is a direction of a normal line to the plane defined by the first direction DR1 and the second direction DR2. In this disclosure, a front surface (or a top surface, an upper surface, or a top side) and a rear surface (or a bottom surface, a lower surface, or a bottom side) of members constituting the electronic apparatus EA may be defined based on the third direction DR3. In addition, in this disclosure, an extending direction of the third direction DR3 is parallel to the thickness direction, the front surface (or the top surface, the upper surface, or the top side) refers to a surface (or a direction) adjacent to a surface on which the image IM is displayed, and the rear surface (or the bottom surface, the lower surface, or the bottom side) refers to a surface (or a direction) separated from the surface on which the image IM is displayed. In this disclosure, the plane refers to a surface parallel to the plane defined by the first direction DR1 and the second direction DR2, and the cross-sectional surface refers to the plane perpendicular to the plane defined by the first direction DR1 and the second direction DR2 and parallel to the thickness direction (e.g., the third direction DR3). In addition, the term “a plan view” or “in plan view” may refer to a state, in which it is viewed from the third direction DR3. And the term “a cross-sectional view” or “in side view” may refer to a state, in which it is viewed from a direction normal to the third direction DR3.

FIG. 4 is an exploded perspective of an electronic apparatus according to one or more embodiments. For example, FIG. 4 is an exploded perspective view of a display device DD included in the electronic apparatus EA. According to one or more embodiments, the display device may be applied to one or more suitable electronic apparatuses. According to one or more embodiments, the display device DD illustrated in FIG. 4 may be a display device included in the electronic apparatus EA according to one or more embodiments and illustrated in FIG. 3.

Referring to FIG. 4, according to one or more embodiments, the display device DD may include a display module DM, a window WP arranged on the display module DM, and an adhesive member AP interposed between the display module DM and the window WP. In addition, the display device DD may further include a housing HAU for receiving the display module DM.

The display device DD illustrated in FIG. 4 may have an outer appearance formed as the window WP and the housing HAU are coupled to each other. The housing HAU may be arranged at a lower side of the display module DM. In one or more embodiments, the housing HAU may include a material having higher rigidity. For example, the housing HAU may include a plurality of frames and/or plates including glass, plastic, or metal. The housing HAU may provide a specific receiving space. The display module DM may be received in the receiving space to be protected from an external impact.

According to one or more embodiments, the adhesive member AP may include a polymer derived from a resin composition. The adhesive member AP may be formed by photo-curing the resin composition. The display module DM and the window WP may be coupled to each other by the adhesive member AP. According to one or more embodiments, the adhesive member AP may include the resin composition (e.g., cured resin composition) according to one or more embodiments to exhibit excellent or suitable adhesion reliability. In addition, according to one or more embodiments, the adhesive member AP may be prevented or reduced from being discolored by external light (e.g., an ultraviolet ray). Hereinafter, the details of the resin composition will be described.

The window WP may include a transmission region TA and a bezel region BZA. The transmission region TA may be overlapped with at least a portion of an active region AA-DM of the display module DM. The transmission region TA may be an optically transparent region. The image IM (see FIG. 3) may be provided to a user through the transmission region TA.

The bezel region BZA may have a light transmittance lower than a light transmittance of the transmission region TA. The bezel region BZA defines a shape of the transmission region TA. The bezel region BZA may be adjacent to the transmission region TA while around (e.g., surrounding) the transmission region TA.

In one or more embodiments, the bezel region BZA may have a specific color. The bezel region BZA may cover at least a portion of a peripheral region NAA-DM of the display module DM to prevent or reduce the peripheral region NAA-DM from being viewed from the outside. However, embodiments of the present disclosure are not limited thereto. For example, in one or more embodiments, the bezel region BZA may be arranged to be adjacent only to one side of the transmission region TA, or at least a portion of the bezel region BZA may not be provided.

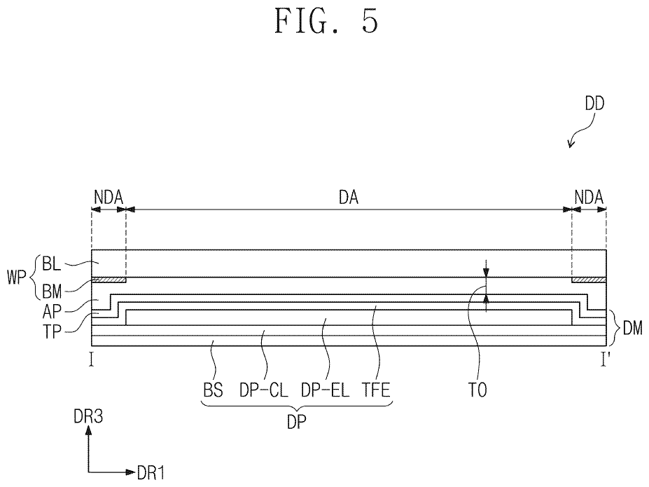

FIG. 5 is a cross-sectional view illustrating a portion taken along the line I-I′ of FIG. 4 according to one or more embodiments of the present disclosure. FIG. 5 is a cross-sectional view illustrating the display device according to one or more embodiments, which includes the display module DM, the adhesive member AP, and the window WP of FIG. 4.

Referring to FIG. 5, in one or more embodiments, the display module DM may include a display panel DP and an input sensing unit TP arranged on the display panel DP. The display panel DP may be a component which substantially generates an image. The display panel DP may include a base substrate BS, a circuit layer DP-CL arranged on the base substrate BS, a display element layer DP-EL arranged on the circuit layer DP-CL, and an encapsulating layer TFE to cover the display element layer DP-EL. The adhesive member AP may be interposed between the display module DM and the window WP. If (e.g., when) the display module DM includes the display panel DP and the input sensing unit TP, the adhesive member AP may be interposed between the input sensing unit TP arranged on the display panel DP and the window WP.

The configuration of the display panel DP illustrated in FIG. 5 is provided only for the illustrative purpose, and is not limited thereto. For example, in one or more embodiments, the display panel DP may include a liquid crystal display element. In these embodiments, the encapsulating layer TFE may not be provided.

The base substrate BS may provide a base surface on which the circuit layer DP-CL is arranged. The base substrate BS may be a flexible substrate which is bendable, foldable, and rollable. The base substrate BS may be a glass substrate, a metal substrate, or a polymer substrate. However, embodiments of the present disclosure are not limited thereto. For example, in one or more embodiments, the base substrate BS may include an inorganic layer, an organic layer, or a composite material layer.

The circuit layer DP-CL may include an insulating layer, a semiconductor pattern, a conductive pattern, and a signal line. For example, the circuit layer DP-CL may include switching transistor(s) and driving transistor(s) to drive a light emitting element ED (see FIG. 6) of the display element layer DP-EL, which will be described in more detail later.

The display element layer DP-EL may include the light emitting element ED (see FIG. 6). For example, the light emitting element ED (see FIG. 6) may include an organic light emitting material, an inorganic light emitting material, an organic-inorganic light emitting material, a quantum dot, a quantum rod, a micro-LED, or a nano-LED.

The encapsulating layer TFE may be arranged on the display element layer DP-EL. The encapsulating layer TFE may protect the display element layer DP-EL from foreign substances such as moisture, oxygen, and dust particles. The encapsulating layer TFE may include at least one inorganic layer. For example, in one or embodiments, the encapsulating layer TFE may include an inorganic layer, an organic layer, and an inorganic layer sequentially stacked.

The input sensing unit TP may be arranged on the display panel DP. For example, in one or more embodiments, the input sensing unit TP may be directly arranged on the encapsulating layer TFE of the display panel DP. In one or more embodiments, an adhesive layer may be interposed between the input sensing unit TP and the display panel DP.

In this disclosure, if (e.g., when) one component is directly arranged on another component, a third component is not interposed/provided between the one component and the another component. For example, if (e.g., when) the one component is “directly arranged” on the another component, the one component makes “contact” with the another component.

The input sensing unit TP may sense an external input (e.g., a touch of a user), may change the sensed input into an input signal, and may provide the input signal to the display panel DP. For example, for the display device DD according to one or more embodiments, the input sensing unit TP may be a touch sensing unit to sense a touch. The input sensing unit TP may recognize a direct touch by a user, an indirect touch by the user, a direct touch by an object, or an indirect touch by the object.

The input sensing unit TP may sense at least one of a position or a strength (pressure) of a touch applied from the outside. According to one or more embodiments, the input sensing unit TP may have one or more suitable structures or may include one or more suitable materials, but embodiments of the present disclosure are not limited thereto. For example, in one or more embodiments, the input sensing unit TP may sense an external input in a capacitive manner. The display panel DP may receive an input signal from the input sensing unit TP and may generate an image corresponding to the input signal.

The window WP may include a base layer BL and a printing layer BM. In one or more embodiments, the window WP may further include at least one functional layer provided on the base layer BL. For example, the functional layer may include a hard coating layer, and/or an anti-fingerprint coating layer, but embodiments of the present disclosure are not limited thereto.

In one or more embodiments, the base layer BL may include a glass substrate. In one or more embodiments, the base layer BL may include a plastic substrate. For example, the base layer BL may include polyimide, polyacrylate, polymethylmethacrylate, polycarbonate, polyethylenenaphthalate, polyvinylidene chloride, polyvinylidene difluoride, polystyrene, an ethylene vinylalcohol copolymer, or a combination thereof.

The printing layer BM may be arranged on a (e.g., one) surface of the base layer BL. The printing layer BM may be provided on a bottom surface of the base layer BL, which is adjacent to the display module DM. The printing layer BM may be arranged at an edge region of the base layer BL. In one or more embodiments, the printing layer BM may include an ink printing layer. In one or more embodiments, the printing layer BM may be a layer including a pigment and/or a dye. In one or more embodiments, the printing layer BM may be formed by including a light absorbing material, or may be formed by including black pigment(s) and/or black dye(s).

However, embodiments of the present disclosure are not limited thereto. In the window WP, the bezel region BZA (see FIG. 4) may be a part that provides the printing layer BM.

A thickness TO of the adhesive member AP may be in a range of about 50 μm to 300 about μm. For example, in one or more embodiments, the adhesive member AP may have the thickness TO in a range of about 50 μm to about 250 μm. However, this is provided only for the illustrative purpose, the thickness TO of the adhesive member AP is not limited thereto.

FIG. 6 is a cross-sectional view illustrating the display module DM of FIG. 5 in more detail according to one or more embodiments. The configuration of the display module DM illustrated in FIG. 6 is provided only for the illustrative purpose, and embodiments of the present disclosure are not limited thereto.

In FIG. 6, the base substrate BS may include a single layer or a multi-layer. For example, in one or more embodiments, the base substrate BS may include a first synthetic resin layer, a multi-layer or single-layer inorganic layer, and a second synthetic resin layer arranged on the multi-layer or single-layer inorganic layer. In one or more embodiments, each of the first synthetic resin layer and the second synthetic resin layer may include a polyimide-based resin. In one or more embodiments, each of the first synthetic resin layer and the second synthetic resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. In this disclosure, the “~-based” resin refers to include a functional group of “~”.

The display panel DP may include a transistor TR and the light emitting element ED. The transistor TR and the light emitting element ED may be arranged on the base substrate BS. Although one transistor TR is illustrated in FIG. 6, the display panel DP may include a plurality of transistors and at least one capacitor to substantially drive the light emitting element ED.

The circuit layer DP-CL may be arranged on the base substrate BS. The circuit layer DP-CL may include a shielding electrode BML, the transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stack structure of the circuit layer DP-CL illustrated in FIG. 6 is provided only for the illustrative purpose. For example, the stack structure of the circuit layer DP-CL may be varied depending on the configuration of the display panel DP and the process of the circuit layer DP-CL.

The shielding electrode BML may be arranged on the base substrate BS. The shielding electrode BML may overlap with the transistor TR. The shielding electrode BML may block light incident on the transistor TR from a lower portion of the display panel DP to protect the transistor TR. The shielding electrode BML may include a conductive material. When a voltage is applied to the shielding electrode BML, a threshold voltage of the transistor TR arranged on the shielding electrode BML may be maintained. However, embodiments of the present disclosure are not limited thereto, and the shielding electrode BML may be a floating electrode. In one or more embodiments, the shielding electrode BML may not be provided.

The buffer layer BFL may be arranged on the base substrate BS to cover the shielding electrode BML. The buffer layer BFL may include an inorganic layer. The buffer layer BFL may improve a bonding force between a semiconductor pattern or a conductive pattern arranged on the buffer layer BFL and the base substrate BS.

The transistor TR may include a source S1, a channel C1, a drain D1, and a gate G1. The source S1, the channel C1, and the drain D1 of the transistor TR may be formed from a semiconductor pattern. The semiconductor pattern of the transistor TR may include polysilicon, amorphous silicon, or a metal oxide. The semiconductor pattern may include one or more suitable materials without limitation, as long as the materials have semiconductor properties.

The semiconductor pattern may include a plurality of regions divided depending on the strength of the conductivity. In the semiconductor pattern, a region doped with dopants or a region in which a metal oxide is reduced shows a greater conductivity. Substantially, such a region may serve as a source electrode or a drain electrode of the transistor TR. The regions showing the greater conductivity in the semiconductor pattern may correspond to the source S1 and the drain D1 of the transistor TR. A region, which is not doped or doped at a lightly concentration, or a region, which shows a lower conductivity, as the metal oxide is not reduced, may correspond to the channel C1 (or active) of the transistor TR.

The first insulating layer INS1 may cover the semiconductor pattern of the transistor TR and may be arranged on the buffer layer BFL. The gate G1 of the transistor TR may be arranged on the first insulating layer INS1. In a plan view, the gate G1 may be overlapped with the channel C1 of the transistor TR. The gate G1 may serve as a mask during a process for doping the semiconductor pattern of the transistor TR.

The second insulating layer INS2 may be arranged on the first insulating layer INS1 to cover the gate G1. The third insulating layer INS3 may be arranged on the second insulating layer INS2.

To connect the transistor TR and the light-emitting element ED, the connection electrode CNE may include a first connection electrode CNE1 and a second connection electrode CNE2. However, the configuration of the connection electrode CNE to electrically connect the transistor TR to the light emitting element ED is not limited thereto. For example, in one or more embodiments, one of the first and second connection electrodes CNE1 and CNE2 may not be provided, or an additionally connection electrode may be further included.

The first connection electrode CNE1 may be arranged on the third insulating layer INS3. In one or more embodiments, the first connection electrode CNE1 may be connected to the drain D1 through a first contact hole CH1 formed through the first to third insulating layers INS1 to INS3. The fourth insulating layer INS4 may be arranged on the third insulating layer INS3 to cover the first connection electrode CNE1. The fifth insulating layer INS5 may be arranged on the fourth insulating layer INS4.

The second connection electrode CNE2 may be arranged on the fifth insulating layer INS5. The second connection electrode CNE2 may be connected to the first connection electrode CNE1 through a second contact hole CH2 formed through the fourth and fifth insulating layers INS4 and INS5. A sixth insulating layer INS6 may be arranged on the fifth insulating layer INS5 to cover the second connection electrode CNE2.

Each of the first to sixth insulating layers INS1 to INS6 may include an inorganic layer or an organic layer. For example, the inorganic layer may include at least one of an aluminum oxide, a titanium oxide, a silicon oxide, a silicon oxynitride, a zirconium oxide, or a hafnium oxide. The organic layer may include at least one of an acrylic-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer DP-EL may include a pixel defining film PDL and the light emitting element ED. The light emitting element ED may include a first electrode AE, a hole control layer HCL, an emission layer EML, an electron control layer TCL, and a second electrode CE.

The first electrode AE may be arranged on the sixth insulating layer INS6. The first electrode AE may be connected to the second connection electrode CNE2 through a third contact hole CH3 formed through the sixth insulating layer INS6. The first electrode AE may be electrically connected to the drain D1 of the transistor TR through the first and second connection electrodes CNE1 and CNE2.

The first electrode AE may include a metal material, a metal alloy, or a conductive compound. The first electrode AE may be an anode or a cathode. In addition, the first electrode AE may be a pixel electrode. The first electrode AE may be a transmission electrode, a semi-transmission electrode, or a reflective electrode. The first electrode AE may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more of the foregoing, or an oxide thereof.

If (e.g., when) the first electrode AE is a transmission electrode, the first electrode AE may include a transparent metal oxide, for example, indium tin oxide (ITO), indium zinc oxide (IZO), zinc oxide (ZnO), and/or indium tin zinc oxide (ITZO). If (e.g., when) the first electrode AE is a semi-transmission electrode or a reflective electrode, the first electrode AE may include Ag, Mg, Cu, Al, Pt, Pd, Au, Ni, Nd, Ir, Cr, Li, Ca, LiF/Ca (the stack structure of LiF and Ca), LiF/Al (the stack structure of LiF and Al), Mo, Ti, W, a compound thereof, or a mixture thereof (for example, a mixture of Ag and Mg). In one or more embodiments, the first electrode AE may have a multi-layer structure including a reflective layer or a semi-transmission layer formed of one or more of the above materials and a transparent conductive layer formed of indium tin oxide (ITO), indium zinc oxide (IZO), zinc oxide (ZnO), or indium tin zinc oxide (ITZO). For example, in one or more embodiments, the first electrode AE may include a three-layer structure of ITO/Ag/ITO, but embodiments of the present disclosure are not limited thereto. In one or more embodiments, the first electrode AE may include one of the above-described metal materials, a combination of at least two types (kinds) metal materials selected from the above-described metal materials, or an oxide of the above-described metal materials.

The pixel defining film PDL may be arranged on the sixth insulating layer INS6. The pixel defining film PDL may include a polymer resin. For example, in one or more embodiments, the pixel defining film (PDL) may be formed by including a polyacrylate-based resin or a polyimide-based resin. In one or more embodiments, the pixel defining film PDL may further include an inorganic material in addition to a polymer resin. The pixel defining film PDL may be formed by including a light absorbing material, or may be formed by including black pigment(s) or black dye(s). The pixel defining film PDL formed by including a black pigment and/or a black dye may implement a black pixel defining film. In one or more embodiments, when the pixel defining film PDL is formed, carbon black may be used as the black pigment or the black dye, but embodiments of the present disclosure are not limited thereto.

In one or more embodiments, the pixel defining film PDL may include an inorganic material. For example, the pixel defining film PDL may include an inorganic material such as silicon nitride (SiNₓ), or silicon oxide (SiOₓ), silicon oxynitride (SiOₓN_{y}). An emission opening PX_OP may be defined in the pixel defining film PDL to expose a portion of the first electrode AE. The portion of the first electrode AE exposed through the emission opening PX_OP may be defined as an emission region LA.

The active region AA-DM of the display module DM may include the emission region LA and a shielding region NLA. The region for disposing the pixel defining film PDL may correspond to the shielding region NLA. The shielding region NLA may surround the emission region LA, in the active region AA-DM.

The hole control layer HCL may be arranged on the first electrode AE and the pixel defining film PDL. The hole control layer HCL may be provided as a common layer overlapping both (e.g., simultaneously) the emission region LA and the shielding region NLA. The hole control layer HCL may include at least one of a hole transport layer, a hole injection layer, or an electron blocking layer. The hole control layer HCL may include a hole injection material suitable in the art and/or a hole transport material suitable in the art.

The emission layer EML may be arranged on the hole control layer HCL. In one or more embodiments, the emission layer EML may be arranged in a region corresponding to the emission opening PX_OP. In one or more embodiments, the emission layer EML may be provided as a common layer. The emission layer EML may include an organic light emitting material and/or an inorganic light emitting material. The emission layer EML may be to emit any one of red, green, and blue color lights. For example, in one or more embodiments, the emission layer EML may be to emit blue color light.

The electron control layer TCL may be arranged on the emission layer EML. The electron control layer TCL may be provided as a common layer overlapping both (e.g., simultaneously) the emission region LA and the shielding region NLA. The electron control layer TCL may include at least one of an electron transport layer, an electron injection layer, or a hole blocking layer. The electron control layer TCL may include an electron injection material suitable in the art and/or an electron transport material suitable in the art.

The second electrode CE may be arranged on the electron control layer TCL. The second electrode CE may be provided as a common layer overlapping both (e.g., simultaneously) the emission region LA and the shielding region NLA.

The second electrode CE may be a common electrode. The second electrode CE may be a cathode or an anode. For example, if (e.g., when) the first electrode AE is an anode, the second electrode CE may be a cathode. If (e.g., when) the first electrode AE is a cathode, the second electrode CE may be an anode.

The second electrode CE may be a transmission electrode, a semi-transmission electrode, or a reflective electrode. If (e.g., when) the second electrode CE is a transmission electrode, the second electrode CE may include a transparent metal oxide, for example, indium tin oxide (ITO), indium zinc oxide (IZO), zinc oxide (ZnO), and/or indium tin zinc oxide (ITZO).

If (e.g., when) the second electrode CE is a semi-transmission electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In one or more embodiments, the second electrode CE may have a multi-layer structure including a reflective layer or a semi-transmission layer including one or more of the above materials and a transparent conductive layer formed of indium tin oxide (ITO), indium zinc oxide (IZO), zinc oxide (ZnO), or indium tin zinc oxide (ITZO). For example, in one or more embodiments, the second electrode CE may include one of the above-described metal materials, a combination of at least two types (kinds) metal materials selected from the above-described metal materials, or an oxide of the above-described metal materials.

The encapsulating layer TFE may be arranged on the second electrode CE to cover the light emitting element ED. The encapsulating layer TFE may include a plurality of thin films. For example, in one or more embodiments, the encapsulating layer TFE may include inorganic films arranged on the second electrode CE and an organic film interposed between the inorganic films. The inorganic film may protect the light emitting element ED from moisture/oxygen, and the organic film may protect the light emitting element ED from foreign substances such as dust particles.

The input sensing unit TP may include a first sensing insulating layer IL1, a second sensing insulating layer IL2, and a third sensing insulating layer IL3. The input sensing unit TP may include at least one conductive layer arranged on the sensing insulating layers. For example, in one or more embodiments, the input sensing unit TP may include a first conductive layer CDL1 and a second conductive layer CDL2.

The first sensing insulating layer IL1 may be directly arranged on the encapsulating layer TFE. The first sensing insulating layer IL1 may include at least one inorganic insulating layer. In one or more embodiments, the first sensing insulating layer IL1 may be in contact with the encapsulating layer TFE. In one or more embodiments, the first sensing insulating layer IL1 may not be provided. In these embodiments, the first conductive layer CDL1 may be in contact with the encapsulating layer TFE.

In one or more embodiments, the first conductive layer CDL1 may be arranged on the first sensing insulating layer IL1. The first conductive layer CDL1 may include a plurality of first conductive patterns. The plurality of first conductive patterns may be arranged on the first sensing insulating layer IL1. The second sensing insulating layer IL2 may be arranged on the first sensing insulating layer IL1 to cover at least a portion of the first conductive layer CDL1.

The second conductive layer CDL2 may be arranged on the second sensing insulating layer IL2. The second conductive layer CDL2 may include a plurality of second conductive patterns. The plurality of second conductive patterns may be arranged on the second sensing insulating layer IL2. Each of the plurality of second conductive patterns may be connected to the plurality of first conductive patterns through a contact hole formed in the second sensing insulating layer IL2.

The plurality of first conductive patterns of the first conductive layer CDL1 and the plurality of second conductive patterns of the second conductive layer CDL2 may each be arranged to correspond to the shielding region NLA. The plurality of first conductive patterns of the first conductive layer CDL1 and the plurality of second conductive patterns of the second conductive layer CDL2 may each correspond to a mesh pattern.

The third sensing insulating layer IL3 may be arranged on the second sensing insulating layer IL2 to cover the second conductive layer CDL2. Each of the second sensing insulating layer IL2 and the third sensing insulating layer IL3 may include an inorganic insulating layer or an organic insulating layer.

Each of the first conductive layer CDL1 and the second conductive layer CDL2 may have a single layer structure or a multi-layer structure stacked in the third direction DR3. Each of the conductive layers CDL1 and CDL2 having the single layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), and/or indium zinc tin oxide (IZTO). In one or more embodiments, the transparent conductive layer may include a conductive polymer such as poly(3,4-ethylenedioxythiophene) (PEDOT), a metal nanowire, or a graphene.

The conductive layers CDL1 and CDL2 having the multi-layer structure may each include metal layers. The metal layers may have, for example, a three-layer structure of titanium (Ti)/aluminum (Al)/titanium (Ti). In one or more embodiments, the conductive layers CDL1 and CDL2 having the multi-layer structure may each include at least one metal layer and at least one transparent conductive layer.

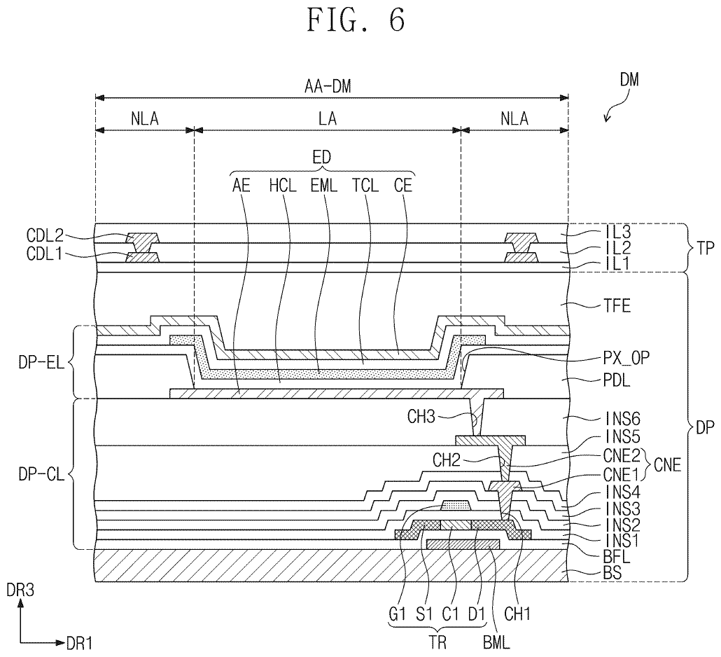

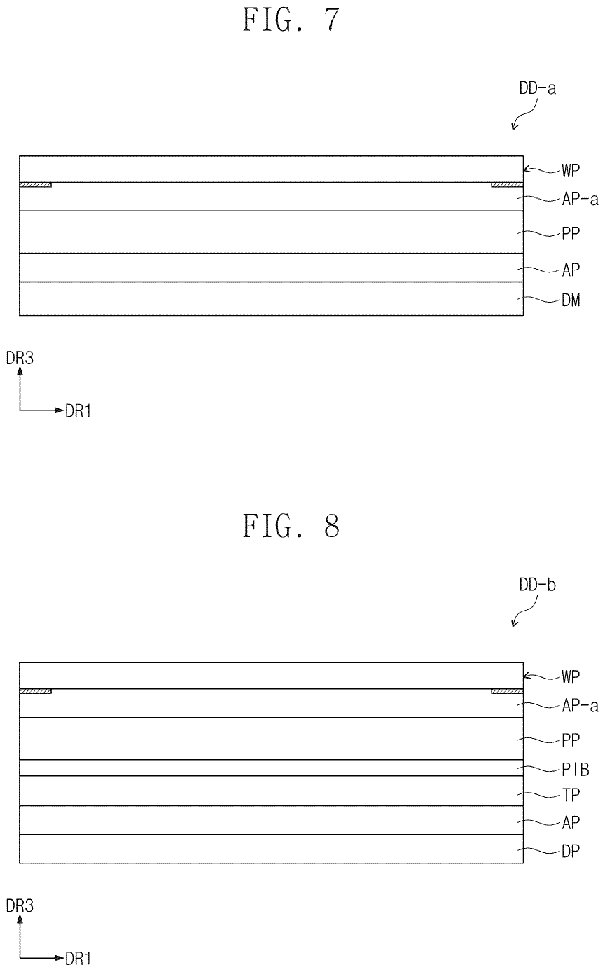

Each of FIGS. 7 and 8 is a cross-sectional view illustrating a display device according to one or more embodiments of the present disclosure. The following description about the display device will be made with reference to FIGS. 7 and 8 while focusing on the difference from the display device of FIGS. 1 to 6, and the repetition with the description made with reference to FIGS. 1 to 6 will not be provided to avoid redundant.

When compared to the display device DD made with reference to FIGS. 4 and 5, a display device DD-a illustrated in FIG. 7 may further include a light control layer PP and an optical adhesive layer AP-a. According to one or more embodiments, the display device DD-a may further include the light control layer PP, which is interposed between the adhesive member AP and the window WP, and the optical adhesive layer AP-a which is interposed between the light control layer PP and the window WP. The light control layer PP may include a polarizing plate or a color filter layer.

The optical adhesive layer AP-a may be formed of a resin composition RC according to one or more embodiments, which will be described later. The optical adhesive layer AP-a including a polymer derived from the resin composition RC may exhibit excellent or suitable adhesive strength. The display device DD-a including the optical adhesive layer AP-a may exhibit the excellent or suitable reliability and the excellent or suitable display quality.

When compared to the display device DD made with reference to FIGS. 4 and 5, a display device DD-b illustrated in FIG. 8 may further include a light control layer PP, an optical adhesive layer AP-a, and an inter-layer adhesive layer PIB. In the display device DD-b according to one or more embodiments, the adhesive member AP may be interposed between the display panel DP and the input sensing unit TP. For example, the input sensing unit TP may be bonded to the display panel DP through the adhesive member AP instead of being directly arranged on the display panel DP. For example, the adhesive member AP may be interposed between the encapsulating layer TFE (FIG. 5) of the display panel DP and the input sensing unit TP.

The inter-layer adhesive layer PIB may be provided under the light control layer PP. The inter-layer adhesive layer PIB may be interposed between the input sensing unit TP and the light control layer PP and may include an adhesive material having an excellent or suitable moisture-proof property. For example, in one or more embodiments, the inter-layer adhesive layer PIB may include polyisobutylene. The inter-layer adhesive layer PIB may be arranged on the input sensing unit TP to prevent or reduce sensing electrodes of the input sensing unit TP from being corroded. According to one or more embodiments, the display device DD-b includes the optical adhesive layer AP-a and the adhesive member AP including the resin composition RC according to one or more embodiments. Accordingly, the display device DD-b including the optical adhesive layer AP-a and the adhesive member AP may exhibit the excellent or suitable reliability and the excellent or suitable display quality.

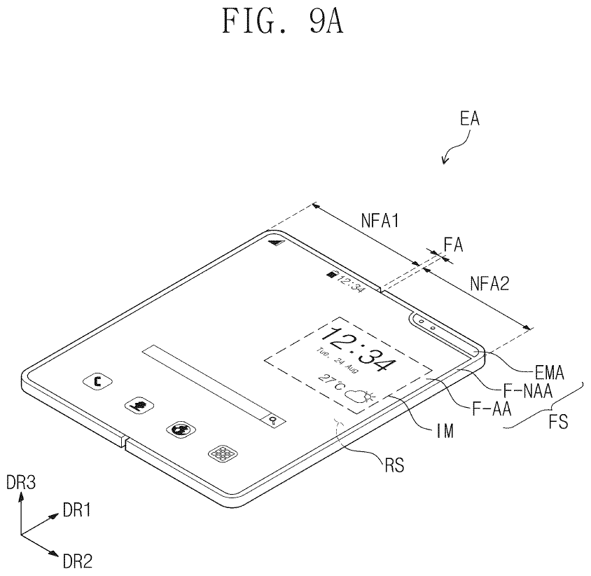

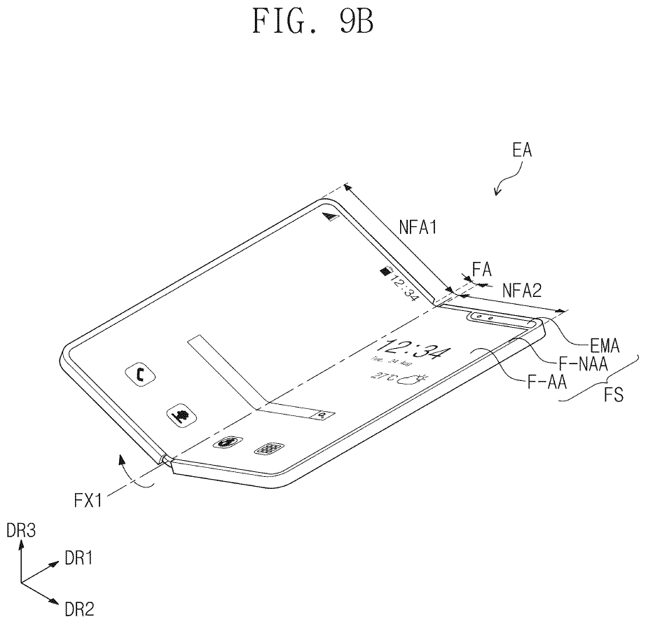

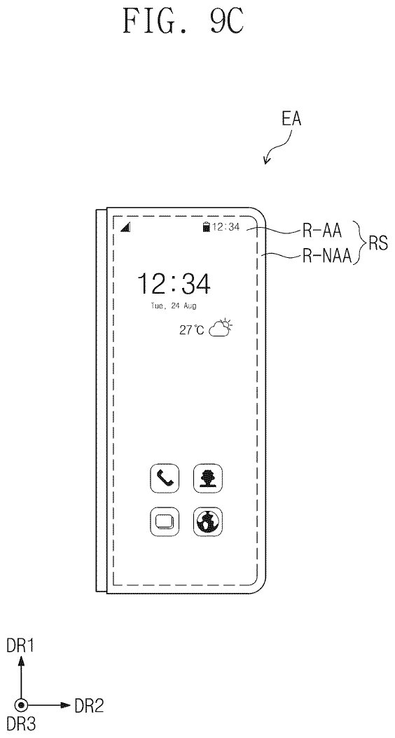

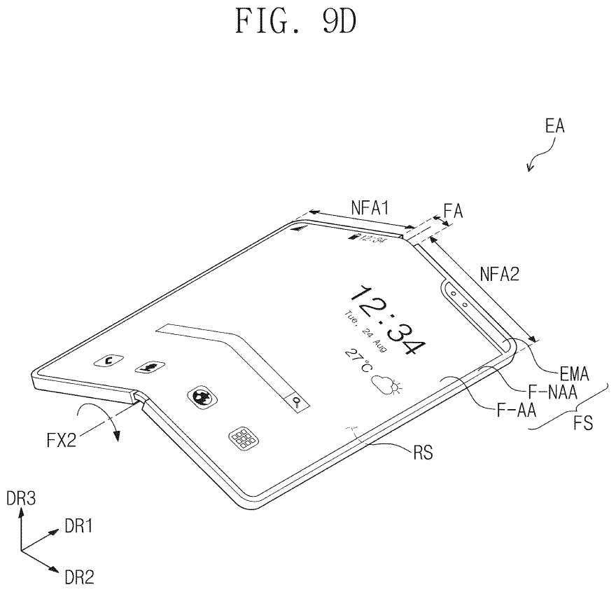

FIGS. 9A to 9D are each a perspective view and a plan view illustrating an electronic apparatus according to one or more embodiments of the present disclosure. The electronic apparatus EA according to one or more embodiments may be flexible. The following description about the electronic apparatus will be made with reference to FIGS. 9A to 9D while focusing on the difference from the electronic apparatuses of FIGS. 1 to 8, and the repetition with the description made with reference to FIGS. 1 to 8 will not be provided to avoid redundant.

FIG. 9A is a perspective view illustrating the electronic apparatus EA unfolded according to one or more embodiments. The electronic apparatus EA according to one or more embodiments may be a device activated in response to an electrical signal. For example, the electronic apparatus EA may be a cellular phone, a tablet, a vehicle navigation system, a game console, or a wearable device, but embodiments of the present disclosure are not limited thereto. FIG. 9A illustrates that the electronic apparatus EA is a cellular phone by way of example.

In this disclosure, the first direction DR1 and the second direction DR2 may be perpendicular to each other. The third direction DR3 may be a direction normal to the plane defined by the first direction DR1 and the second direction DR2. A thickness direction of the electronic apparatus EA may be parallel to the third direction DR3. The front surface (or top surface) and the rear surface (bottom surface) of the electronic apparatus EA are opposite to each other, and a normal direction to the front surface and the rear surface may parallel to the third direction DR3. The front surface (or top surface) refers to a plane adjacent to a first display surface FS, and the rear surface (or the bottom surface) refers to a plane spaced apart from the first display surface FS. In one or more embodiments, the rear surface (or the bottom surface) of the electronic apparatus EA refers to a plane close to a second display surface RS to be described later. An upper portion refers to a portion (e.g., direction) close to the first display surface FS, and a lower portion refers to a portion (e.g., direction) spaced away from the first display surface FS.

The cross-section refers to a surface parallel to the thickness direction DR3, and the plane may refer to a surface normal to the thickness direction (third direction DR3). The plane refers to a plane defined by the first direction DR1 and the second direction DR2.

The directions indicated by the first to third directions DR1, DR2, and DR3, in the disclosure, is a relative concept and may be changed to another direction. In addition, the directions indicated by the first to third directions DR1, DR2, and DR3 will be referred to as the first to third directions and will be assigned with the same reference numerals.

The electronic apparatus EA may sense an external input applied from the outside. The external input may include one or more suitable types (kinds) of inputs which are provided from the outside of the electronic apparatus EA. For example, besides a contact by a part of a body of a user, for example, a user hand, the external input may include an external input (for example, a hovering input) which is applied in a state in which the user hand approaches the electronic apparatus EA or is adjacent to the electronic apparatus EA within a specific distance. In addition, the external input may have one or more suitable types (kinds) such as force, pressure, a temperature, and a light.

The electronic apparatus EA may include the first display surface FS and the second display surface RS. The first display surface FS may include a first active region F-AA, a first peripheral region F-NAA, and an electronic module region EMA. The second display surface RS may be defined as a surface which is opposite to at least a portion of the first display surface FS. For example, the second display surface RS may be defined as a portion of a rear surface of the electronic apparatus EA.

The first active region F-AA may be activated in response to an electrical signal. The first active region F-AA may be a region for displaying an image IM and for sensing one or more suitable types (kinds) of external inputs.

The first peripheral region F-NAA may be adjacent to the first active region F-AA. In one or more embodiments, the first peripheral region F-NAA may have some colors. In one or more embodiments, the first peripheral region F-NAA may surround the first active region F-AA. Accordingly, a shape of the first active region F-AA may be substantially defined by the first peripheral region F-NAA. However, this is provided only for the illustrative purpose, in one or more embodiments, the first peripheral region F-NAA may be arranged to be adjacent only to one side of the first active region F-AA or may not be provided.

Various electronic modules may be arranged in the electronic module region EMA. For example, the electronic module may include at least one of a camera, a speaker, a light sensor, or a thermal sensor. The electronic module region EMA may sense an external subject received through display surfaces FS and RS or may provide a sound signal, such as a voice, to the outside through the display surfaces FS and RS. The electronic module may include a plurality of components and is not particularly limited thereto.

In one or more embodiments, the electronic module region EMA may be surrounded by the first peripheral region F-NAA. However, this is provided only for the illustrative purpose, and embodiments of the present disclosure are not limited thereto. For example, in one or more embodiments, the electronic module region EMA may be surrounded by the first active region F-AA and the first peripheral region F-NAA, and may be arranged in the first active region F-AA.

The electronic apparatus EA according to one or more embodiments may be flexible. According to one or more embodiments, the electronic apparatus EA may include at least one folding region FA and non-folding regions NFA1 and NFA2 extending from the folding region FA. For example, the first non-folding region NFA1, the folding region FA, and the second non-folding region NFA2 may be defined in the second direction DR2. According to one or more embodiments, the electronic apparatus EA may include a first non-folding region NFA1 and a second non-folding region NFA2 which are arranged to be spaced from each other in the second direction DR2 while interposing the folding region FA between the first non-folding region NFA1 and the second non-folding region NFA2. For example, the first non-folding region NFA1 may be arranged at one side of the folding region FA in the second direction DR2, and the second non-folding region NFA2 may be arranged at the other side (e.g., a side opposite the one side) of the folding region FA in the second direction DR2.

Although FIG. 9A illustrates the electronic apparatus EA including one folding region FA according to one or more embodiments, embodiments of the present disclosure are not limited thereto. For example, in one or more embodiments, a plurality of folding regions may be defined in the electronic apparatus EA. For example, in one or more embodiments, the electronic apparatus may include at least two folding regions, and at least three non-folding regions arranged such that the folding regions are interposed among the at least three non-folding regions.

FIG. 9B is a perspective view illustrating a folding operation of the electronic apparatus EA according to one or more embodiments. FIG. 9C is a plan view illustrating the electronic apparatus EA folded according to one or more embodiments. FIG. 9D is a perspective view illustrating a folding operation of the electronic apparatus EA according to one or more embodiments.

Referring to FIG. 9B, according to one or more embodiments, the electronic apparatus EA may be folded about a first folding axis FX1 extending in the first direction DR1. When the electronic apparatus EA is folded, the folding region FA may have a specific curvature or a specific radius of curvature. For example, in one or more embodiments, the radius of curvature of the folding region FA may be at most about 5 mm. The electronic apparatus EA may be folded about the first folding axis FX1, and changed to be in an in-folding state in which the first non-folding region NFA1 and the second non-folding region NFA2 face each other, and the first display surface FS is not exposed to the outside.

Referring to FIG. 9C, according to one or more embodiments, when the electronic apparatus EA is in the in-folding state, the second display surface RS may be viewed by a user. In this regard, the second display surface RS may include a second active region R-AA to display an image. The second active region R-AA may be activated in response to an electrical signal. The second active region R-AA may be a region for displaying an image and for sensing one or more suitable types (kinds) of external inputs.

A second peripheral region R-NAA may be adjacent to the second active region R-AA. In one or more embodiments, the second peripheral region R-NAA may have some colors. In one or more embodiments, the second peripheral region R-NAA may surround the second active region R-AA. In one or more embodiments, in the electronic apparatus EA, even the second display surface RS may further include an electronic module region for disposing an electronic module including one or more suitable components, and embodiments of the present disclosure are not limited thereto.

Referring to FIG. 9D, according to one or more embodiments, the electronic apparatus EA may be folded about a second folding axis FX2 extending in the first direction DR1. When the electronic apparatus EA is folded, the folding region FA may have a specific curvature or a specific radius of curvature. For example, in one or more embodiments, the radius of curvature of the folding region FA may be at most about 5 mm. The electronic apparatus EA may be folded about the second folding axis FX2, and changed to be in an out-folding state such that the first display surface FS is exposed to the outside. According to one or more embodiments, the electronic apparatus EA may be configured such that the switch from an unfolding state to an in-folding or out-folding state and the switch from the in-folding or out-folding state to the unfolding state are repeated, but embodiments of the present disclosure are not limited thereto.

Although FIGS. 9A to 9D illustrate that the folding is performed about one folding axis FX1 or FX2, the number of folding axes and the number of non-folding regions based on the folding axis are not limited thereto. For example, as the electronic apparatus EA are folded about a plurality of folding axes, the first display surface FS and the second display surface RS may partially face each other. In addition, although it is illustrated that the first and second folding axes FX1 and FX2 are each parallel to a longer side of the electronic apparatus EA, embodiments of the present disclosure are not limited thereto. For example, in one or more embodiments, the first and second folding axes FX1 and FX2 may each be parallel to a shorter side of the electronic apparatus EA.

In the electronic apparatus EA, the first non-folding region NFA1 and the second non-folding region NFA2 may be defined as portions having the display surfaces FS and RS parallel to a plane defined by the first direction DR1 and the second direction DR2, if (e.g., when) the electronic apparatus EA is folded as illustrated in FIG. 9C. The folding region FA may be defined as a region between the first non-folding region NFA1 and the second non-folding region NFA2. The folding region FA may include a curved surface bent to have a specific curvature, if (e.g., when) the electronic apparatus EA is folded. For example, the radius of curvature of the folding region FA may be at most about 5 mm.

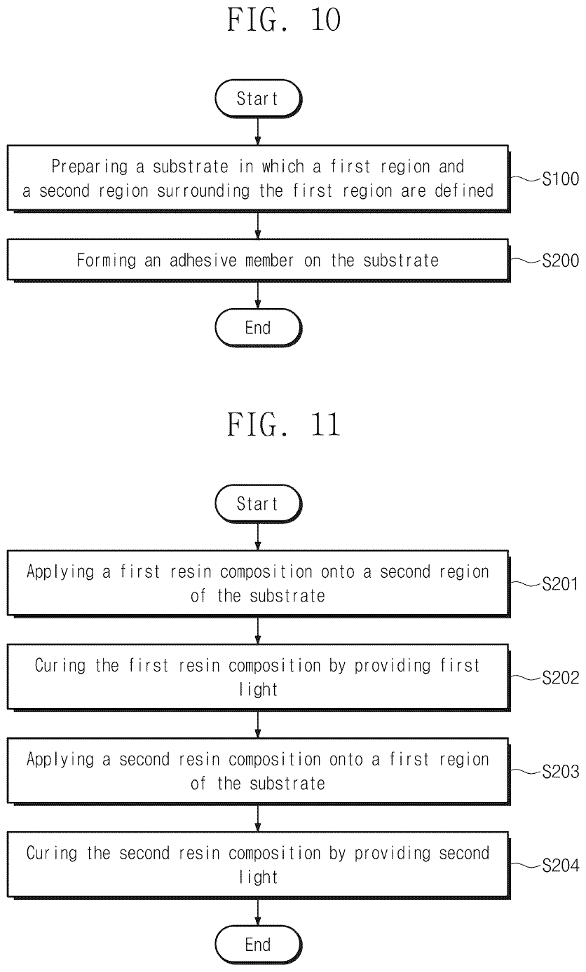

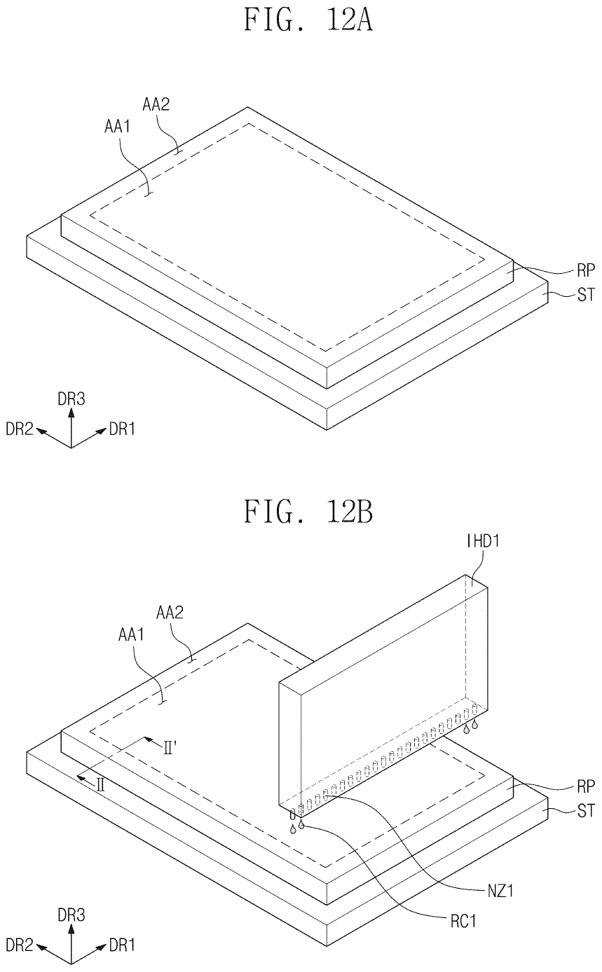

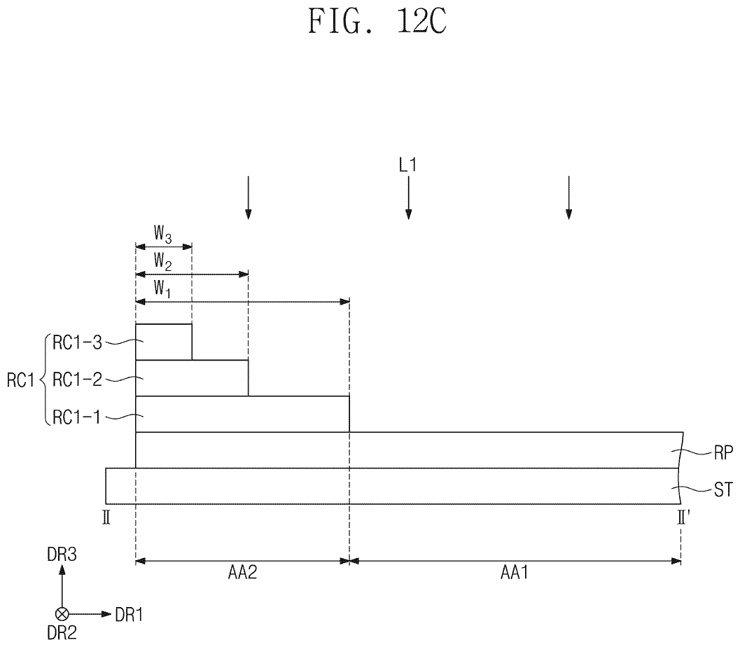

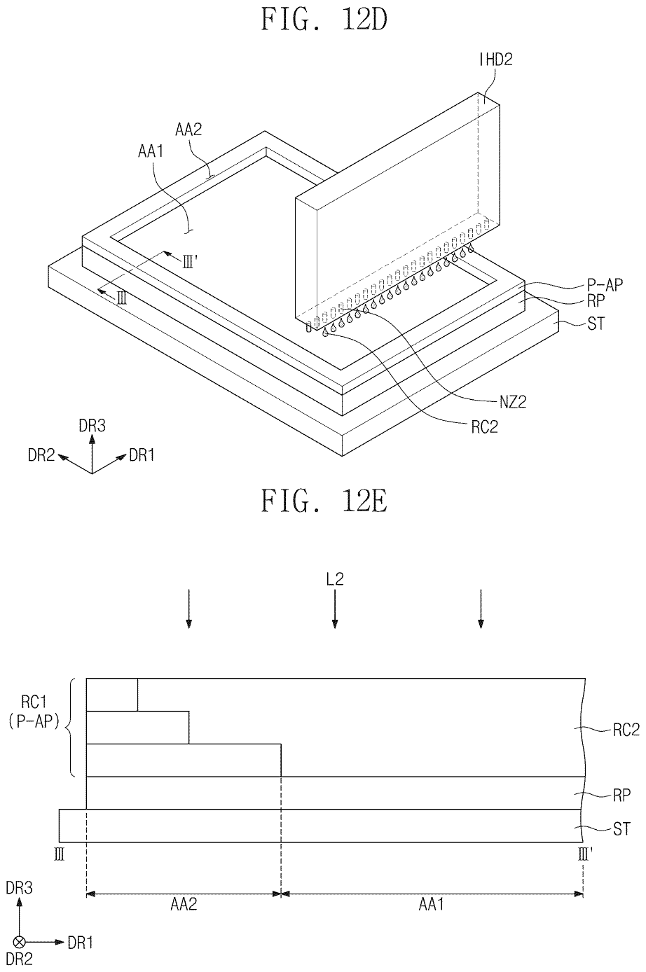

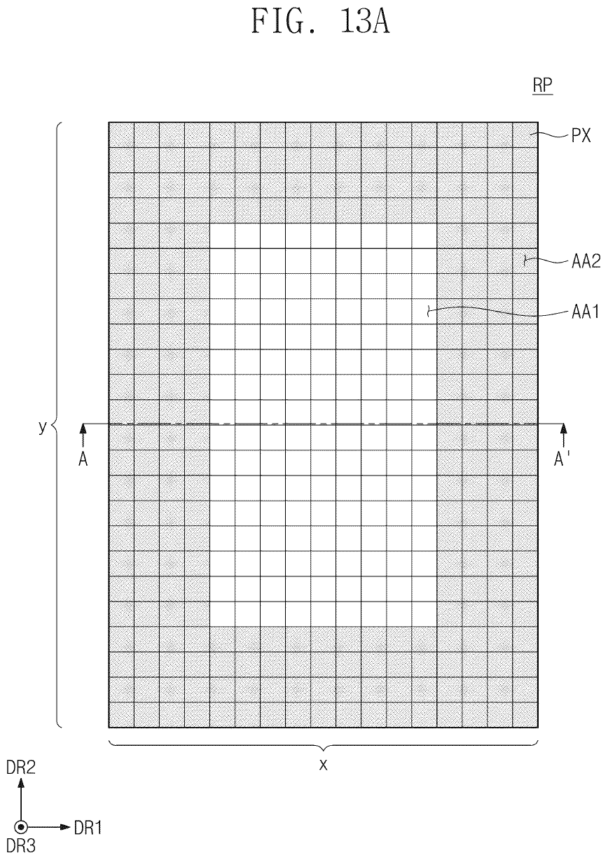

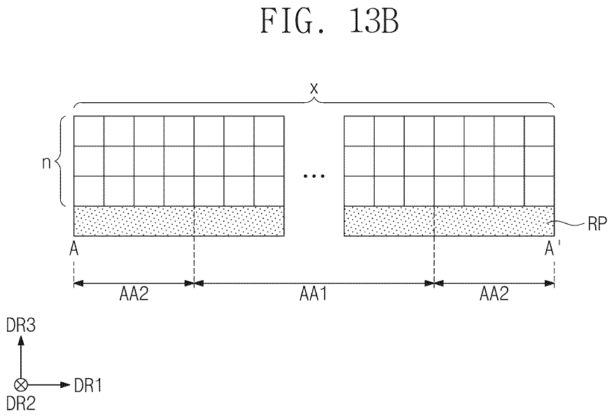

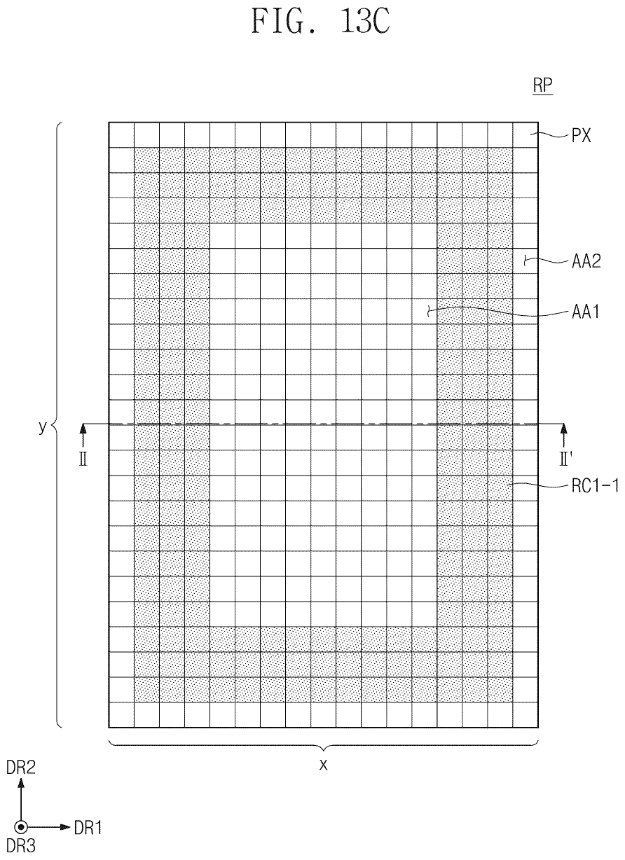

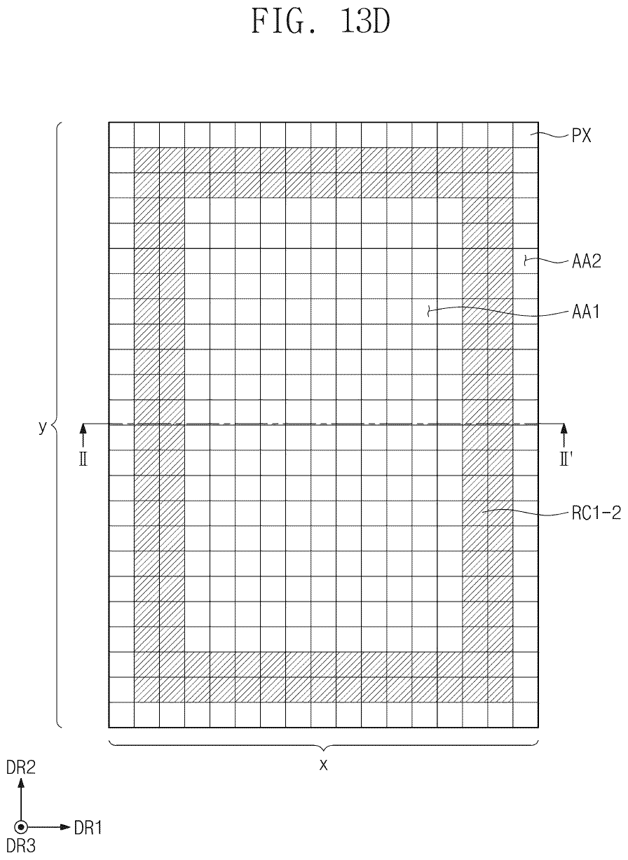

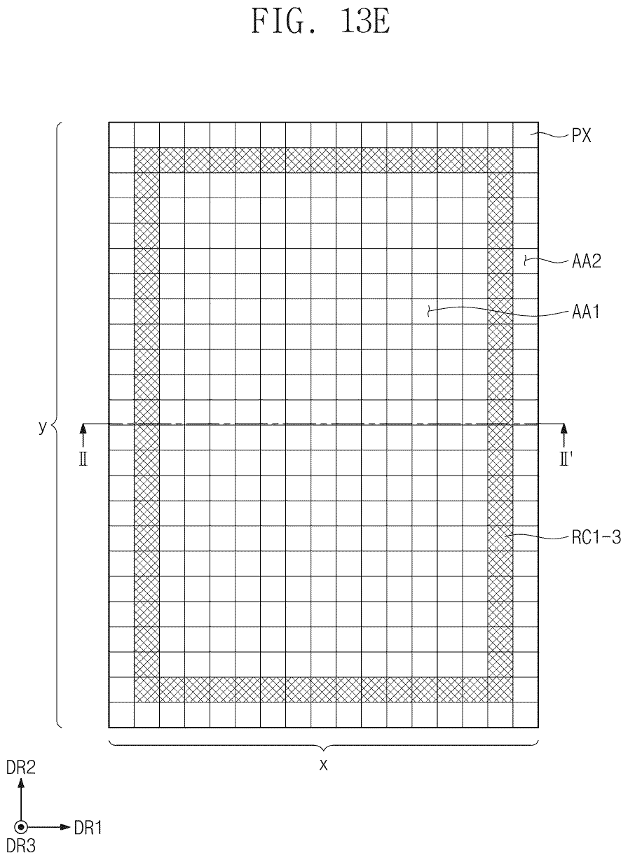

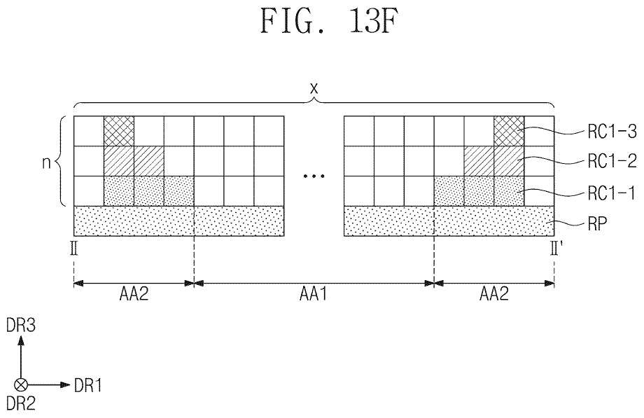

FIG. 10 is a flowchart illustrating a method for manufacturing the electronic apparatus EA according to one or more embodiments of the present disclosure. FIG. 11 is a flowchart illustrating a method (e.g., manner) for forming the adhesive member according to one or more embodiments of the present disclosure. FIGS. 12A to 12E are views schematically illustrating the method (e.g., manner) for forming the adhesive member AP according to one or more embodiments. FIGS. 13A to 13F are views schematically illustrating the method (e.g., manner) for forming the adhesive member AP according to one or more embodiments.

According to one or more embodiments, the adhesive member AP may be formed by using a resin composition. The adhesive member AP may include a polymer derived from the resin composition. The polymer derived from the resin composition may be formed by photo-curing the resin composition. The above description about the electronic apparatus EA is applicable to the description about the electronic apparatus EA in the following description about the method for manufacturing the electronic apparatus EA according to one or more embodiments. In the following description on the method for manufacturing the electronic apparatus EA, the electronic apparatus EA will be described while focusing on the difference from the above-description, and the duplication of description of the electronic apparatus EA according to one or more embodiments will not be provided to avoid redundancy.

The method for manufacturing the electronic apparatus according to one or more embodiments may represent the method for manufacturing the electronic apparatus including, for example, the display device DD, DD-a, or DD-b according to one or more embodiments, which has been described with reference to FIGS. 1 to 9. According to one or more embodiments, provided is a method for manufacturing the electronic apparatus including the adhesive member AP arranged on the display module DM of the display device DD, DD-a, or DD-b.

Referring to FIG. 10, the method for manufacturing the electronic apparatus EA according to one or more embodiments may include the steps (e.g., actions or tasks) of preparing a substrate, in which a first region and a second region around (e.g., surrounding) the first region are defined (S100), and forming the adhesive member AP on the substrate (S200).

For example, the method for manufacturing the electronic apparatus EA according to one or more embodiments may include preparing the display module DM in which a first region AA1 and a second region AA2 (see FIGS. 12A to 12E), which surrounds the first region AA1, are defined, forming the adhesive member AP on the display module DM in an inkjet printing scheme (e.g., inkjet printing process), and bonding the window WP to the display module DM through the adhesive member AP.

Referring to FIG. 11, the step for forming the adhesive member AP (S200) according to one or more embodiments may include the steps for applying a first resin composition onto a second region of the substrate (S201), curing the first resin composition by providing (e.g., irradiating) first light (S202), applying a second resin composition onto a first region of the substrate (S203), and curing the second resin composition by providing (e.g., irradiating) second light (203).

In this disclosure, the step for applying the first resin composition (S201) may be referred to as a first applying step, and the step for applying the second resin composition (S203) may be referred to as a second applying step.

Referring to FIG. 12A, the step for preparing for a substrate RP, in which a first region and a second region around (e.g., surrounding) the first region are defined (S100), may precede the first applying step, before the adhesive member AP is formed. In this regard, the step for seating the substrate RP on a stage ST may be performed together. The step for seating the substrate RP on the stage ST may be a step for preparing for the substrate RP to form the adhesive member.

The substrate RP may provide a reference surface (e.g., application surface) for forming the adhesive member AP. For example, in one or more embodiments, the substrate RP may be the display module DM, the display panel DP, or the window WP described above. In one or more embodiments, the substrate RP may include, for example, polyethylene terephthalate (PET). However, a material for the substrate RP is not particularly limited thereto, as long as the material is appropriately or suitably used by those skilled in the art.

The stage ST may provide a space to seat the substrate RP. The stage ST may be provided in a plate form. Although FIG. 12A illustrates that the stage ST has a rectangular shape in a plan view, embodiments of the present disclosure are not limited thereto. For example, the plan view shape and the plan view size of the stage ST may be suitably changed.

A temperature of the stage ST may be in a range of about 20 °C to about 30 °C while the adhesive member AP is formed. If (e.g., when) the temperature of the stage ST is less than 20 °C, the substrate RP is colder than the normal temperature, condensation may be formed. In addition, if (e.g., when) the temperature of the stage ST exceeds 30 °C, some components of the resin composition may be volatilized, and the characteristics of the adhesive member may be changed after curing.

The first region AA1 and the second region AA2 may be defined in the substrate RP. The first region AA1 and the second region AA2 may be suitably set on the substrate RP for an inkjet printing process to be described later. The first region AA1 may correspond to a central portion of the substrate RP. The second region AA2 may correspond to an edge portion of the substrate RP, rather than the first region AA1. The second region AA2 may surround the first region AA1, on the plane defined by the first direction DR1 and the second direction DR2.

The first region AA1 may have an area larger than that of the second region AA2 in a plan view. According to one or more embodiments, the first region AA1 of the substrate RP may correspond to at least a portion of the display region DA of the electronic apparatus EA (see FIG. 3). In addition, the second region AA2 of the substrate RP may correspond to at least a portion of the non-display region NDA of the electronic apparatus EA (see FIG. 3).

According to one or more embodiments, the second region AA2 may have an average width of at most about 5 mm. The average width of the second region AA2 may be in a range of about 0.1 mm to about 2.0 mm. The average width of the second region AA2 may refer to an average of a horizontal distance from an edge of the substrate RP to a boundary between the first region AA1 and the second region AA2, when viewed in the third direction DR3 (e.g., in plan view).

FIG. 12B illustrates the step for applying a first resin composition RC1 (S201) in the method for manufacturing the electronic apparatus AP according to one or more embodiments. FIG. 12C illustrates the step for curing the first resin composition RC1 by irradiating a first light L1 (S202) after the first applying step. FIG. 12C is a cross-sectional view of a portion corresponding to the line II-II′ of FIG. 12B according to one or more embodiments.

Referring to FIG. 12B, the first resin composition RC1 may be applied to the second region AA2 of the substrate RP. The first resin composition RC1 may be provided on the substrate RP through the inkjet printing process. The first resin composition RC1 may be discharged from a first inkjet head IHD1 and provided on the substrate RP.

The first inkjet head IHD1 may be arranged above the stage ST. The first inkjet head IHD1 may be arranged to be spaced and/or apart (e.g., spaced apart or separated) from a top surface of the stage ST by a specific or set distance to perform a discharge process for discharging the first resin composition RC1 from the first inkjet head IHD1 on the substrate RP.

The first inkjet head IHD1 may include a plurality of first nozzles NZ1. The plurality of first nozzles NZ1 may be arranged to be spaced from each other by a specific or set distance in one direction. The plurality of first nozzles NZ1 may be aligned in line with each other. However, embodiments of the present disclosure are not limited thereto. In one or more embodiments, the plurality of first nozzles NZ1 may be aligned in at least two lines. Each of the plurality of first nozzles NZ1 may discharge ink toward the substrate RP. For example, a discharge direction of each of the plurality of first nozzles NZ1 may be perpendicular to the substrate RP. However, embodiments of the present disclosure are not limited thereto.

In one or more embodiments, each of the plurality of first nozzles NZ1 may include a discharge port having the form of a cylindrical hole. However, embodiments of the present disclosure are not limited thereto. The shape of the discharge port of each first nozzle NZ1 may be suitably changed. In addition, the number and the size of the plurality of first nozzles NZ1 included in the first inkjet head IHD1 may be suitably changed.

The plurality of first nozzles NZ1 included in the first inkjet head IHD1 may be independently controlled or selected by a controller. The controller may control the discharge of the first resin composition RC1 of each of the first nozzles NZ1, such that ink is applied in a desired or suitable shape on the substrate RP. In addition, the first inkjet head IHD1 may further include a storage unit to store the first resin composition RC1 to be discharged to the substrate RP.

Referring to FIGS. 12B and 12C, the first applying step, which is the step for applying the first resin composition RC1 to the second region AA2 of the substrate RP (S201), may be performed at least twice. In one or more embodiments, the first applying step (S201) may be performed n times (2≤n≤5; n is an integer). In the first applying step performed multiple times, an applying layer may be formed to be overlapped with an applying layer formed in an immediately preceding first applying step. In one or more embodiments, the first applying step (S201) may be performed two times or three times, but the number of times of applying the first resin composition may be varied depending on an applying amount.

In the first applying step, which is performed at a first phase (e.g., first time among n times), the first resin composition RC1 may be applied to the second region AA2 such that the applying layer is entirely overlapped with the second region AA2. For example, the first applying step may be a process for applying the first resin composition RC1 to the entirety of the second region AA2. In one or more embodiments, the first resin composition RC1 may be applied to the second region AA2 except for a margin at the outer most portion of the substrate RP. When the first resin composition RC1 may be applied to the second region AA2 except for the margin at the outer most portion of the substrate RP, the first resin composition RC1 may be prevented or reduced from leaking. In this regard, the margin may have a size of about at most 2 mm.

The first applying step (S201) may be performed up to n times in total. In this regard, n is an integer in a range of 2 to 5. FIG. 12C illustrates a cross-sectional surface after the first applying step (S201) is performed three times. However, the number of times to perform the first applying step is provided only for the illustrative purpose, and embodiments of the present disclosure are not limited thereto.

Referring to FIG. 12C, a first resin composition RC1-2, which is applied at a second phase, is stacked on a first resin composition RC1-1 which is applied at a first phase. In addition, a first resin composition RC1-3, which is applied at a third phase, is stacked on the first resin composition RC1-2 which is applied at the second phase.

The first resin compositions, which are stacked after the first applying step (S201) is performed multiple times, are in a liquid state. Accordingly, the stacked first resin compositions may have a gently curved shape. However, in FIGS. 12A to 12E and 13A to 13H including FIG. 12C, the stacked first resin compositions are shown in the form of a block for the convenience for expression. Accordingly, the cross-section according to one or more embodiments is not limited to those of FIGS. 12A to 12E and 13A to 13H.

An outer peripheral portion of the first resin composition applied at an n-th phase may be overlapped with an outer peripheral portion of the first resin composition applied at an (n−1)-th phase. The outer peripheral portion may refer to an outer edge or a circumferential portion of the outer most portion (e.g., a portion distal to the first region AA1 of the substate RP), based on a plan view when viewed in the third direction DR3.

An inner peripheral portion of the first resin composition applied at the n-th phase may be different from an inner peripheral portion of the first resin composition applied in the (n−1)-th phase. In this regard, the wording “~different from~” may refer to “~not overlapped with~”. The inner peripheral portion may refer to an inner edge or an inner circumferential portion (e.g., a portion in proximity to the first region AA1 of the substate RP), when viewed from the third direction DR3 (e.g., in plan view).

A width (Wₙ) of the first resin composition applied at the n-th phase, may be smaller than a width (Wₙ₋₁) of the first resin composition applied at the (n−1)-th phase. A width of the first resin composition applied, may refer to a horizontal distance from the outer peripheral portion to the inner peripheral portion, when viewed from the third direction DR3 (e.g., in plan view).

For example, the width (W₂) of the first resin composition RC1-2 applied at the second phase may be smaller than the width (W₁) of the first resin composition RC1-1 applied at the first phase. In addition, the width (W₃) of the first resin composition RC1-3 applied at the third phase may be smaller than the width (W₂) of the first resin composition RC1-2 applied at the second phase.

The step for applying the first resin composition RC1 may be a step for applying the first resin composition RC1 to the second region AA2 depending on a set application amount. In the step for applying the first resin composition RC1, the first inkjet head IHD1 may discharge the first resin composition RC1 to the second region AA2 while moving in the second direction DR2. However, embodiments of the present disclosure are not limited thereto. In one or more embodiments, the first inkjet head IHD1 may discharge the first resin composition RC1 while moving in the first direction DR1.

A total applying amount of the first resin composition applied at the n-th phase may be less than a total applying amount of the first resin composition applied at the (n−1)-th phase.

In one or more embodiments, an applying amount per unit area of the first resin composition applied at the n-th phase or at the first phase may be in a range of about 0.041 g/inch² to about 0.076 g/inch². An applying amount per unit area of the first resin composition applied at the n-th phase may be less than an applying amount per unit area of the first resin composition applied at the (n−1)-th phase.

A total area of the first resin composition applied at the n-th phase may be smaller than a total area of the first resin composition applied at the (n−1)-th phase. In this regard, the total area of the first resin composition may be measured based on the plan view when viewed from the third direction DR3.

When the first resin composition is applied to the second region to be overlapped multiple times before the second resin composition is applied to the first region, the delamination of the adhesive member may be minimized or reduced due to surface tension or drying.

Referring back to FIG. 12C, after the first applying step (S201) is performed, the first light L1 may be irradiated to cure the first resin composition. The first light L1 may be irradiated into the first resin composition, which is in the liquid state, provided on the substrate RP. The first resin composition RC1 applied through the first applying step (S201) may be cured by the first light L1 to form a polymer. When the first resin composition RC1 is cured by the first light L1, a preliminary adhesive member P-AP (see FIG. 12D) may be formed. Hereinafter, the first resin composition RC1 cured in this disclosure may be used with the same meaning as that of the preliminary adhesive member P-AP (see FIG. 12D).

The first light L1 may be an ultraviolet ray, but embodiments of the present disclosure are not limited thereto. The first light L1 may include a light having a single wavelength, or having multiple wavelengths.

According to one or more embodiments, the first light L1 may include both (e.g., simultaneously) UVA and UVV, or may include only UVA. As used herein, the term “UVA” may refer to an ultraviolet ray having a wavelength in the range of about 320 nm to about 390 nm, and the term “UVV” may refer to a near-visible ultraviolet ray having a wavelength in the range of about 395 nm to about 445 nm.

According to one or more embodiments of the present disclosure, the illuminance of UVA included in the first light L1 may be in a range of about 400 mW/cm² to about 1,200 mW/cm². An accumulated light amount of the UVA included in the first light L1 may be in a range of about 300 mJ/cm² to about 700 mJ/cm². When the first light L1 includes both (e.g., simultaneously) UVA and UVV, an illuminance of the UVV may be in a range of about 200 mW/cm² to about 600 mW/cm². When the first light L1 includes both (e.g., simultaneously) UVA and UVV, an accumulated light amount of the UVV may be in a range of about 120 mJ/cm² to about 150 mJ/cm².

For example, in one or more embodiments, if (e.g., when) both (e.g., simultaneously) UVA and UVV are used as the first light L1, the illuminance of the UVA may be in a range of about 400 mW/cm² to about 800 mW/cm², and the illuminance of the UVV may be in a range of about 200 mW/cm² to about 600 mW/cm². In these embodiments, the accumulated light amount of the UVA may be in a range of about 300 mJ/cm² to about 400 mJ/cm², and the accumulated light amount of the UVV may be in a range of about 120 mJ/cm² to about 150 mJ/cm².

For example, in one or more embodiments, if (e.g., when) the first light L1 includes only UVA, the illuminance of the UVA may be in a range of about 800 mW/cm² to about 1,200 mW/cm². In these embodiments, the accumulated light amount of the UVA may be in a range of about 400 mJ/cm² to about 700 mJ/cm².

However, the above-described first light L1 is provided only for the illustrative purpose, and embodiments of the present disclosure are not limited to the above examples, as long as those skilled in the art may appropriately or suitably select the light. The first light L1 may be substantially identical to or different from a second light L2 to be described later.

An amount of first light L1 irradiated onto the first resin composition RC1 in the step for curing the first resin composition RC1 may be a light amount sufficient to completely cure the first resin composition RC1. However, embodiments of the present disclosure are not limited thereto. For example, in one or more embodiments, a polymerization reaction of the first resin composition RC1 may be partially performed in the step for curing the first resin composition RC1, and thereafter, an uncured portion of the first resin composition RC1 may be further reacted to form the adhesive member AP (see FIG. 12D) at a final phase, in a step for curing the second resin composition RC2.

The first resin composition RC1 will be described later together with the second resin composition RC2.

FIG. 12D illustrates the step (S203) for applying the second resin composition RC2 in the method for manufacturing the adhesive member AP according to one or more embodiments.

The second resin composition RC2 may be provided on the substrate RP through the inkjet printing process. The second resin composition RC2 may be discharged from a second inkjet head IHD2 and provided on the substrate RP.

The second inkjet head IHD2 may be arranged above the stage ST. The second inkjet head IHD2 may be arranged to be spaced and/or apart (e.g., spaced apart or separated) from the top surface of the stage ST by a specific or set distance to perform a discharge process for discharging the second resin composition RC2 from the second inkjet head IHD2 on a portion or an entirety of the cured first resin composition RC1 and on the first region AA1 of the substrate RP.

The second inkjet head IHD2 may include a plurality of second nozzles NZ2. The plurality of second nozzles NZ2 may be arranged to be spaced from each other by a specific or set distance in one direction. The plurality of second nozzles NZ2 may be aligned in line with each other. However, embodiments of the present disclosure are not limited thereto. In one or more embodiments, the plurality of second nozzles NZ2 may be aligned in at least two lines. Each of the plurality of second nozzles NZ2 may discharge ink toward the substrate RP. For example, a discharge direction of each of the plurality of second nozzles NZ2 may be perpendicular to the substrate RP. However, embodiments of the present disclosure are not limited thereto.

In one or more embodiments, each of the plurality of second nozzles NZ2 may include a discharge port having the form of a cylindrical hole. However, embodiments of the present disclosure are not limited thereto. The shape of the discharge port of each second nozzle NZ2 may be suitably changed. In addition, the number and the size of the plurality of second nozzles NZ2 included in the second inkjet head NZ2 may be suitably changed.

The plurality of second nozzles NZ2 included in the second inkjet head IHD2 may be independently controlled or selected by the controller. The controller may control the discharge of the second resin composition RC2 of each of the second nozzles NZ2, such that ink is applied in a desired or suitable shape on the substrate RP. In addition, the second inkjet head IHD2 may further include a storage unit to store the second resin composition RC2 to be discharged to the substrate RP.

According to one or more embodiments, the first inkjet head IHD1, which discharges the first resin composition RC1, may be the same as the second inkjet head IHD2 which discharges the second resin composition RC2. However, embodiments of the present disclosure are not limited thereto.

FIG. 12E is a view illustrating the step (S204) for curing the second resin composition RC2 by irradiating the second light L2 in the method for manufacturing the adhesive member AP. FIG. 12E is a cross-sectional view of a portion corresponding to line Ill-III′ of FIG. 12D according to one or more embodiments.

Referring to FIGS. 12D and 12E, the step for applying the second resin composition RC2 may be performed such that the second resin composition RC2 is overlapped with a portion or an entirety of the preliminary adhesive member P-AP and the first region AA1 of the substrate RP. In this regard, the portion or the entirety of the preliminary member P-AP refers to the portion or the entirety of the first resin composition RC1. The portion, which is overlapped with the second resin composition RC2, of the first resin composition RC1 may refer to the first resin composition RC1 positioned on the second region AA2 adjacent to the first region AA1. For example, the second resin composition RC2 may be applied in the form having a continuous surface to cover the portion of the first resin composition RC1 cured and the first region AA1.

The preliminary adhesive member P-AP illustrated in FIGS. 12D and 12E may be formed through the steps for applying the first resin composition (S201), and for curing the first resin composition by irradiating the first light (S202). Although FIGS. 12D and 12E illustrate that the preliminary adhesive member P-AP is in the form of a block, the preliminary adhesive member P-AP is formed by applying and curing the first resin composition, which may be different from a real cross-section of the preliminary adhesive member P-AP. In other words, FIGS. 12D and 12E illustrate schematic views, and the real shape of the preliminary adhesive member P-AP of one or more embodiments is not limited thereto.

An amount of the second resin composition RC2 applied per unit area (e.g., an applying amount per unit area of the second resin composition) may be in a range of about 0.041 g/inch² to about 0.076 g/inch². An amount of the first resin composition RC1 applied at the n-th phase or the first phase may be equal to the amount of the second resin composition RC2 applied per unit area.

Referring to FIG. 12E, the step for curing the second resin composition RC2 (S204) may be performed after the step for applying the second resin composition RC2 (S203). The second light L2 may be irradiated onto the second resin composition RC2 provided on the substrate RP. The second light L2 may be irradiated to the second resin composition RC2 to cure the second resin composition RC2. The second resin composition RC2 is polymerized and cured by the second light L2 irradiated, to form the adhesive member AP together with the preliminary adhesive member P-AP. Although FIG. 12E illustrates that the second light L2 is irradiated to the first region AA1 and the second region AA2, embodiments of the present disclosure are not limited thereto. For example, in one or more embodiments, the second light L2 may be selectively irradiated only to the first region AA1 depending on the curing degree of the preliminary adhesive member P-AP.

The second light L2 may be an ultraviolet ray, but embodiments of the present disclosure are not limited thereto. The second light L2 may include a light having a single wavelength, or having multiple wavelengths.

According to one or more embodiments, the second light L2 may include both (e.g., simultaneously) UVA and UVV, or may include only UVA.

In one or more embodiments, an accumulated light amount of the UVA included in the second light L2 may be in a range of about 400 mJ/cm² to about 1,200 mJ/cm². In one or more embodiments, an accumulated light amount of the UVA included in the second light L2 may be in a range of about 300 mJ/cm² to about 700 mJ/cm². When the second light L2 includes both (e.g., simultaneously) UVA and UVV, the illuminance of the UVV may be in a range of about 200 mW/cm² to about 600 mW/cm². When the second light L2 includes both (e.g., simultaneously) UVA and UWV, an accumulated light amount of the UVV may be in a range of about 120 mJ/cm² to about 150 mJ/cm².

For example, in one or more embodiments, if (e.g., when) both (e.g., simultaneously) UVA and UVV are used as the second light L2, the illuminance of the UVA may be in a range of about 400 mW/cm² to about 800 mW/cm², and the illuminance of the UVV may be in a range of about 200 mW/cm² to about 600 mW/cm². In these embodiments, the accumulated light amount of the UVA may in a range of about 300 mJ/cm² to about 400 mJ/cm², and the accumulated light amount of the UVV may be in a range of about 120 mJ/cm² to about 150 mJ/cm².

For example, in one or more embodiments, if (e.g., when) the second light L2 includes only UVA, the illuminance of the UVA may be in a range of about 800 mW/cm² to about 1,200 mW/cm². In these embodiments, the accumulated light amount of the UVA may be in a range of about 400 mJ/cm² to about 700 mJ/cm².

However, the above-described second light L2 is provided only for the illustrative purpose, and embodiments of the present disclosure are not limited thereto, as long as those skilled in the art appropriately or suitably select the second light L2.

A curing rate of the second resin composition RC2 may be in range of about 50% to about 85% as calculated by Equation 1, after the second resin composition RC2 is cured by the second light L2. In this regard, the curing rate may be measured to determine the degree of curing progress of the resin composition.

Curing rate (%)=(cured PI₈₁₀/cured PI₁₇₃₀)/(uncured PI₈₁₀/uncured PI₁₇₃₀)×100 Equation 1

In Equation 1, PI₈₁₀ represents a peak intensity of about 810 cm⁻¹ measured by Fourier Transform Infrared Spectroscopy (FT-IR), and PI₁₇₃₀ represents a peak intensity of about 1730 cm⁻¹ measured by FT-IRPI810 is used to determine the C═C double bond, and PI₁₇₃₀ is used to determine the C═O carbonyl group. For example, the curing rate may be used as an index to measure the degree of curing by measuring the reduction in the C═C double bond and the formation of the carbonyl group. Here, for example, the curing rate may be quantified by the reduction of the C═C absorption at about 810 cm⁻¹ relative to a reference carbonyl absorption at about 1730 cm⁻¹ present in the composition. Also, for example, PI₁₇₃₀ may correspond to a carbonyl absorption present in the composition and may be utilized as an internal reference.

The curing rate may be a value obtained through the measurement for the region in which the second resin composition RC2 and the first resin composition RC1 are not overlapped with each other. In one or more embodiments, the curing rate may refer to a curing rate measured at the central part of the cured second resin composition RC2 (e.g., the cured second resin composition RC2 located at the central part of the first region AA1).

If (e.g., when) the curing rate of the second resin composition RC2 is less than 50%, insufficient curing may decrease adhesive strength, and deteriorate the physical strength. Additionally, chemical stability may be insufficient due to unreacted residual monomers. If (e.g., when) the curing rate of the second resin composition RC2 exceeds 85%, internal stress may increase to cause cracks or the delamination of the adhesive member AP.

According to one or more embodiments, the first resin composition RC1 and the second resin composition RC2 may include a same resin composition. However, if (e.g., when) the first resin composition RC1 and the second resin composition RC2 include all characteristics of a resin composition described later, heterogeneous resin compositions may be used. For example, according to one or more embodiments, the first resin composition RC1 and the second resin composition RC2, which are different from each other, are not excluded. In addition, according to one or more embodiments, the first resin composition RC1 including at least two types (kinds) of resin compositions together is not excluded.

In this disclosure, the resin composition may refer to including the first resin composition RC1 and/or the second resin composition RC2. For example, the characteristics of the resin composition to be described later may refer to the common characteristics between the first resin composition RC1 and the second resin composition RC2.

The resin composition may have a viscosity in a range of about 10 mPa·s to about 20 mPa·s at a temperature in a range of about 20 °C to about 30 °C. The viscosity of the resin composition may be the shear viscosity measured in a JIS Z 8803 scheme. For example, the viscosity of the resin composition measured at about 25 °C according to the JIS Z 8803 method may be about 10 mPa·s or higher and about 20 mPa·s or lower.

If (e.g., when) the viscosity of the resin composition at about 25 °C is less than 10 mPa·s, the low viscosity may cause flow of the resin composition provided for forming the adhesive member, which may make it difficult to form an applying layer having a substantially uniform thickness using the resin composition. In addition, if (e.g., when) the viscosity of the resin composition at about 25 °C exceeds 20 mPa·s, the resin composition may not be discharged in an appropriate or suitable amount from an applying device used for applying the resin composition.

The resin composition may be photo-cured under a condition, in which the integrated amount of UV light in the atmosphere (e.g., in air) is in a range of about 4,000 mJ/cm² to about 8,000 mJ/cm², and a 180° peel strength is measured on a glass substrate at about 25 °C. In this regard, the 180° peel strength may be in a range of about 2 kgf/25 mm to about 5 kgf/25 mm, or about 3 kgf/25 mm to about 5 kgf/25 mm. For example, the 180° peel strength may be measured after performing the photo-curing process by using a UV LED lamp having a spectral peak at 395 nm and by irradiating the UV, such that an accumulated light amount of UV light is about 6,000 mJ/cm².

The resin composition may be photo-cured under a condition, in which the accumulated light amount of UV light in the atmosphere (e.g., in air) is in a range of about 4,000 mJ/cm² to about 8,000 mJ/cm², and the 180° peel strength is measured on a glass substrate at about 60 °C. In this regard, the 180° peel strength may be in a range of about 0.5 kgf/25 mm to about 4 kgf/25 mm, or about 1 kgf/25 mm to about 4 kgf/25 mm. For example, the 180° peel strength may be measured after performing the photo-curing process by using a UV LED lamp having a spectral peak at 395 nm and by irradiating the UV, such that an accumulated light amount of UV light is about 6,000 mJ/cm².

When the 180° peel strength of the resin composition is out of the above range, the resin composition may not provide sufficient adhesion to adjacent components of the display device (e.g., the display module and/or window).

The resin composition may have storage modulus in a range of about 0.05 MPa to 0.10 about MPa as measured at about 25 °C, after performing the photo-curing process under conditions in which the accumulated light amount of UV light in the atmosphere (e.g., in air) is in a range of about 4,000 mJ/cm² to about 6,000 mJ/cm². For example, the storage modulus may be measured after performing the photo-curing process under conditions in which the accumulated light amount of UV light in the atmosphere (e.g., in air) is in a range of about 4,000 mJ/cm² by using a UV LED lamp having the spectral peak of 395 nm.

The resin composition may have storage modulus in a range of about 0.05 MPa to about 1.80 MPa as measured at about 60 °C, after photo-curing under conditions in which the accumulated light amount of UV light in the atmosphere (e.g., in air) is in a range of about 4,000 mJ/cm² to about 6,000 mJ/cm². For example, the storage modulus may be measured after performing the photo-curing process by using the UV lamp having the spectral peak at 395 nm and by irradiating the UV light such that the accumulated light amount is about 4000 mJ/cm².

When the storage modulus of the resin composition is below the above range, the adhesive strength may decrease after curing. Additionally, if (e.g., when) the storage modulus of the resin composition exceeds the above range, a void may be formed between the adhesive member AP and the substrate RP after curing.

According to one or more embodiments, the adhesive member AP formed by the method (e.g., manner) for forming the adhesive member AP may prevent the delamination of the substrate RP. The void may be prevented from being formed between the adhesive member AP and the substrate RP. If (e.g., when) the resin composition having the lower viscosity is applied, the shape retention may be difficult. In addition, if (e.g., when) the applied resin composition is curved and shrunken due to the surface-tension, the non-adhesive region may be made. In addition, if (e.g., when) the resin composition exhibits excessively large storage modulus and improper adhesive strength, the resin composition may be cured in a convex form at a terminal end portion to form the void between the adhesive member AP and the substrate RP.

According to one or more embodiments, in the method (e.g., manner) for forming the adhesive member AP, even if the resin composition exhibiting lower viscosity but the excellent or suitable storage modulus and the excellent or suitable adhesive strength after cured is used, the resin composition is prevented from being cured in the convex form at the terminal end portion, thereby preventing the void from being formed between the adhesive member AP and the substrate RP. Accordingly, the delamination between the adhesive member AP and the substrate RP may be prevented.

According to one or more embodiments, an edge gap between the adhesive member AP formed according to one or more embodiments and the substrate RP may be at most about 100 μm, at most about 80 μm, at most about 50 μm, at most about 30 μm, at most 20 about μm, at most about 10 μm, or at most 0 μm. According to one or more embodiments, the edge gap between the adhesive member AP formed according to one or more embodiments and the substrate RP may be in a range of 0 μm to about 100 μm, 0 μm to about 80 μm, 0 μm to about 50 μm, 0 μm to about 30 μm, 0 μm to about 20 μm, 0 μm to about 10 μm, or 0 μm to about 1 μm. For example, in the electronic apparatus EA according to one or more embodiments, the edge gap between the adhesive member AP and the display module or the edge gap between the adhesive member AP and the window may be in a range of 0 μm to about 100 μm.

In this regard, the edge gap is used to determine the delamination degree between the adhesive member AP and the substrate RP. The edge gap may be measured by taking a cross-sectional image of the edge portion using a laser microscope and determining a gap distance (e.g., a distance between the edge of the adhesive member AP and the edge of the substrate RP).

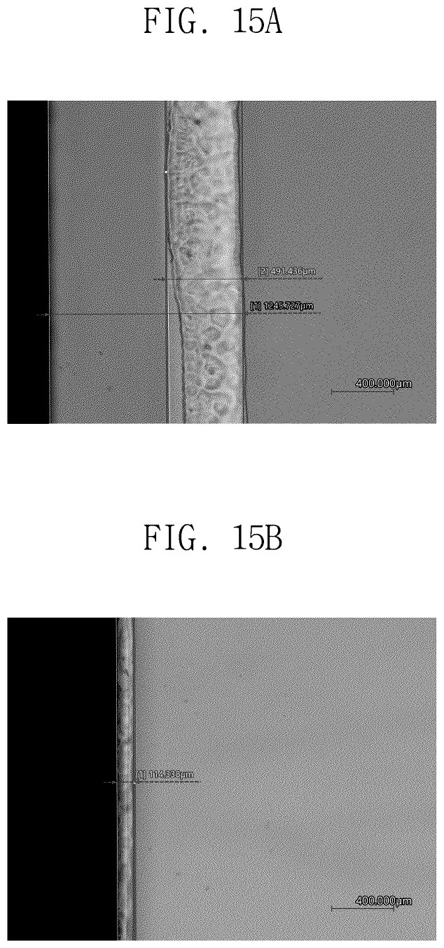

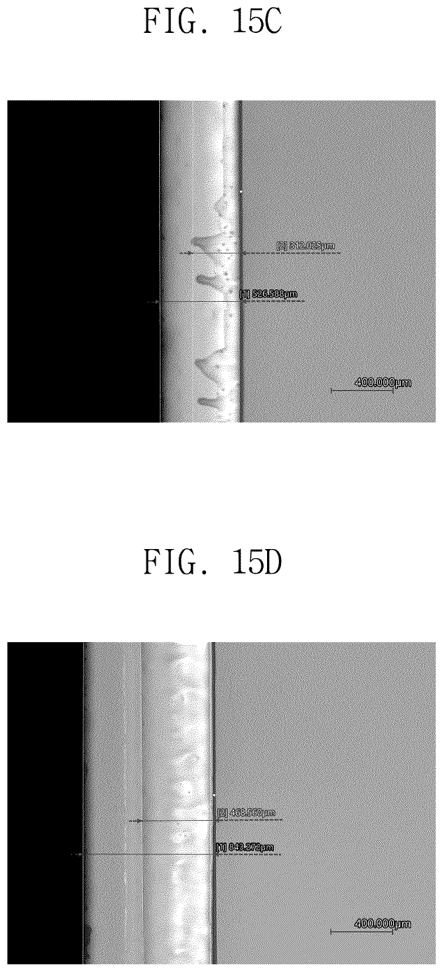

For example, as illustrated in FIGS. 15A to 15D, the edge gap may be determined by measuring the delamination degree between the terminal portions shown from the image of the cross-section taken by the microscope.

For example, as illustrated in FIG. 15A, the edge gap may be about 1,245 μm. This may be a value found by measuring the distance from the glass edge to the bonded portion. For example, as illustrated in FIG. 15A, the edge gap may be a value obtained by measuring a distance from a left white line representing a glass edge to the right most line representing a portion in which the delamination issue is resolved.

As another example, as illustrated in FIG. 15B, the edge gap may be about 114 μm. For example, as illustrated in FIG. 15C, the edge gap may be about 526 μm. For example, as illustrated in FIG. 15D, the edge gap may be about 843 μm. For the manner to measure the edge gap, as described above, the edge gap may be a value obtained by measuring a distance from the leftmost white line representing the terminal portion (e.g., edge portion) of glass to the right most line representing a portion in which the delamination issue is resolved.

The resin composition according to one or more embodiments may have low viscosity before curing and may exhibit excellent or suitable adhesive for after curing.

Even though the adhesive member formed in the method (e.g., manner) for forming the adhesive member according to one or more embodiments or the electronic apparatus EA manufactured through the method for manufacturing the electronic apparatus EA according to one or more embodiments employs the resin composition exhibiting the excellent or suitable storage modulus and the excellent or suitable adhesive strength after curing, the void may be prevented from being formed between the adhesive member and the substrate attached with the adhesive member and the delamination may be prevented from occurred at the terminal end portion.

The electronic apparatus according to one or more embodiments may have excellent or suitable adhesion reliability and structural stability.

The resin composition according to one or more embodiments may include a photopolymerization initiator. The photopolymerization initiator may refer to a substance which absorbs light, such as UV rays and may cause a polymerization reaction of a monomer and/or an oligomer.

For example, the photopolymerization initiator may include at least one of 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

In one or more embodiments, the photopolymerization initiator may include at least one of 2-methyl-1 [4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenyl bis(2,4,6-trimethylbenzoyl)-phosphine oxide, [1-(4-phenylsulfanylbenzoyl)heptylideneamino]benzoate, [1-[9-ethyl-6-(2-methylbenzoyl)carbazol-3-yl]ethylideneamino]acetate, or bis(2,4-cyclopentadienyl)bis[2,6-difluoro-3-(1-pyrryl)phenyl] titanium(IV).

The photopolymerization initiator may be a single type (kind), or at least two types (kinds) of photopolymerization initiators may be combined and used. However, the photopolymerization initiator is not limited to the above types (kinds) of photopolymerization initiators. As long as those skilled in the art appropriately or suitably select the photopolymerization initiator, the range and the kind of the photopolymerization initiators are not limited thereto.

The resin composition may further include one or more additives if necessary. An additive may be appropriately or suitably selected from among generally used additives in the art to adjust the physical properties desired or required for the adhesive composition. For example, the additive may include an ultraviolet stabilizer, a crosslinking agent, an antioxidant, a chain transfer agent, a photosensitizer, a polymerization inhibitor, a leveling agent, a surfactant, an adhesion promoter, a plasticizer, a UV absorber, a storage stabilizer, an antistatic agent, an inorganic filler, a pigment, and/or a dye, but embodiments of the present disclosure are not limited thereto. The additive may include a single material or a mixture of at least two materials.

FIGS. 13A to 13G are views schematically illustrating a method manner for forming an adhesive member according to one or more embodiments of the present disclosure. FIGS. 13A to 13G are views illustrating the manufacturing method shown in FIGS. 10 to 12E described above. Accordingly, the manufacturing method according to one or more embodiments is not limited to those of FIGS. 13A to 13G. In addition, the substrate RP and the applied resin composition, which are illustrated in FIGS. 13A to 13G, are all represented in block shapes for convenience of explanation, but the real shapes thereof according to one or more embodiments are not limited thereto.

In FIGS. 13A to 13G, the second region AA2 may be exaggerated for illustration, and embodiments of the present disclosure are not limited thereto. For example, in actual display devices and electronic apparatuses, the first region AA1 may have an area larger than that of the second region AA2, in a plan view, which is different from illustrations of FIGS. 13A to 13G.

FIGS. 13A and 13B may illustrate a manner for defining the first region AA1 and the second region AA2 on the substrate RP by way of example. FIG. 13B illustrates a cross-section taken along the line A-A′ of FIG. 13A.

Referring to FIG. 13A, according to the method of one or more embodiments, the substrate RP may include a first bitmap including a plurality of pixels PX (e.g., bitmap pixels PX) arranged in the first direction DR1 and the second direction DR2. The substrate RP may be divided into x pixels PX arranged in the first direction DR1 and y pixels PX arranged in the second direction DR2. Therefore, the substrate RP may be divided into x*y pixels PX arranged in the first direction DR1 and the second direction DR2.

Each of the x pixels PX arranged in the first direction DR1 may have the same width based on the first direction DR1, and each of the y pixels PX arranged in the second direction (DR2) may have the same width based on the second direction DR2, but embodiments of the present disclosure are not limited thereto. The length of the substrate RP in the first direction DR1 may be approximately x times the width of the pixel PX in the first direction DR1. The length of the substrate RP in the second direction DR2 may be approximately y times the width of the pixel PX in the second direction DR2.

Referring to FIG. 13B, the resin composition stacked on the substrate RP may constitute n layers. This thickness may result from the first resin composition RC1 is applied n times. Although FIG. 13B illustrates a specific thickness, each layer may have a different thickness depending on an amount of the first resin composition applied. In addition, FIG. 13B is a schematic view illustrating the applying pattern of the resin composition repeatedly applied, instead of the cross-section of the resin composition actually applied. Accordingly, FIG. 13B may be different from the actual cross-section according to one or more embodiments.

The number of pixels PX and the width of the pixels PX in FIG. 13A may be appropriately or suitably adjusted depending on process conditions, and the resolution of inkjet printing equipment, but embodiments of the present disclosure are not limited to the accompanying drawings.

Referring back to FIG. 13A, the step for dividing the first bitmap into the first region AA1 and the second region AA2 may be performed. When viewed in the thickness direction (e.g., in a plan view), the second region AA2 may have a shape around (e.g., surrounding) the first region AA1.

Referring back to FIG. 13B, n may be set depending on the number of times of applying the first resin composition RC1. In this regard, n₁ to nₙ may be defined while starting from the nearest layer respect to the substrate RP. For example, the first resin composition RC1 applied at the first phase may be described as being applied to the n₁ layer in the second region. In addition, the first resin composition RC1 applied at the third phase may be described as being applied to the n₃ layer in the second region.

FIGS. 13C to 13E illustrate that a pattern in the first applying step (S201) is expressed in a bitmap format according to one or more embodiments by way of example, and FIG. 13F is a schematic diagram illustrating the cross-section after the first applying step (S201).

FIG. 13C illustrates the first applying step at the first phase according to one or more embodiments. The first resin composition RC1-1 applied at the first phase may be applied in a pattern as illustrated in FIG. 13C.

FIG. 13D illustrates the first applying step, which is performed at the second phase, according to one or more embodiments. The first resin composition RC1-2 applied at the second phase may be applied in a pattern as illustrated in FIG. 13D.

FIG. 13E illustrates the first applying step, which is performed at the third phase, according to one or more embodiments. The first resin composition RC1-3 applied at the third phase may be applied in a pattern as illustrated in FIG. 13E.

FIG. 13F may be a schematic view illustrating the cross-section of the first resin composition RC1 stacked after the first applying step is performed three times as illustrated in FIGS. 13C to 13E.

Referring to FIGS. 13C to 13E, the first applying step according to one or more embodiments may be performed, for example, three times. For example, the first applying step according to one or more embodiments may be performed multiple times. In the first applying steps of FIGS. 13C to 13E, the same application amount per unit area is applied in each applying performance, but embodiments of the present disclosure are not limited thereto. When the first applying steps (S201) are sequentially performed with patterns as illustrated in FIGS. 13C to 13E, the first resin composition RC1 may be stacked as illustrated in FIG. 13F.

If (e.g., when) the first applying step S201 is performed multiple times, the resin composition may be applied in different patterns within the second region AA2 in each performance. The first applying step performed at the first phase, which is performed with respect to the second region AA2, may be performed till the boundary between the first region AA1 and the second region AA2. The first resin composition applied at the n-th phase (herein, n is an integer greater than or equal to 2) is stacked on the first resin composition applied right before. The first resin composition applied at the second phase to the first resin composition applied at the n-th phase may each be overlapped with the first resin composition applied at the first phase at the outer peripheral portion in the thickness direction. For example, the first resin compositions applied in the first applying step may be overlapped with each other at the outer most portion, when viewed from the third direction (e.g., in plan view).

FIG. 13G illustrates that a pattern in the second applying step (S203) is expressed in a bitmap format according to one or more embodiments by way of example, and FIG. 13H is a schematic diagram illustrating the cross-section after the second applying step (S203) is finished. FIG. 13G may be a view illustrating a pattern in the second applying step (S203) performed after the first applying step is performed as illustrated in FIGS. 13C to 13E.

Referring to FIGS. 13G and 13H, the second resin composition RC2 may be applied in a form having a continuous surface to cover the portion of the first resin composition RC1 cured and the first region AA1. For example, in one or more embodiments, the second resin composition RC2 may be applied in the form having a continuous surface to cover the entirety of the first resin composition RC1 cured and the first region AA1, which is different from FIGS. 13G and 13H. Although FIGS. 13A and 13H illustrate that an amount of the second resin composition RC2 applied per unit area is equal to an amount of the first resin composition RC1 applied per unit area, embodiments of the present disclosure are not limited thereto.

When the resin composition is applied as illustrated in FIGS. 13A to 13H, the applying manner may be formulated as in Equation 2.

AA % (a)_BB % (b)_CC % Equation 2

In Equation 2, % may represent an amount of a resin composition applied. ‘( )’ may indicate the number of pixels on which the resin composition is applied. In addition, Equation 2 shows pixels from the outer most pixels in order, based on the first bitmap. When the number of pixels is not expressed, all the remaining pixels may be intended.

For example, in Equation 2, ‘a’ pixels from the outer most portion may be applied with the resin composition by AA %, ‘b’ pixels may be applied with the resin composition by BB %, and remaining pixels may be applied with the resin composition by CC %, when the resin composition is applied to three region divided from the first bitmap one time.

When the first applying step (S201) and the second applying step (S203) are performed as illustrated in FIGS. 13C to 13E and FIG. 13F, Equation 2 may be expressed as shown in following Table 1.

TABLE 1
First applying step (S201)

| | |
|---|---|
| RC1-3 | 0%(1)_100%(1)_0% |
| RC1-2 | 0%(1)_100%(2)_0% |
| RC1-1 | 0%(1)_100%(3)_0% |

Second applying step (S203)

| | |
|---|---|
| RC2 | 0%(3)_100% |

For example, in Table 1, the second resin composition is not applied to three outer most pixels, and thereafter, is applied to the remaining pixels at an application amount of 100%, when viewed based on the first bitmap.

However, FIGS. 13A to 13H are provided only for the illustrative purpose, and embodiments of the present disclosure are not limited thereto.

Hereinafter, the details of the resin composition according to examples of the present disclosure and an adhesive member including the resin composition will be described with reference to Examples and Comparative examples. In addition, the following embodiments are provided for the illustrative purpose of the present disclosure, but the scope of the present disclosure is not limited thereto.

### EXAMPLE

According to the following Examples and Comparative examples, the adhesive member was formed by using one type (kind) of resin composition. For example, the first resin composition is the same as the second resin composition. Table 2 shows the physical properties of the resin compositions according to an example and a comparative example. The physical property of the resin composition was measured as follows.

### Measurement of Shear Viscosity

The shear viscosity of the resin composition was measured at a temperature of 25 °C and at 10 rpm in compliance with JIS Z 8803 using a resin composition viscometer (TVE-25L, TOKI SANGYO).

### Measurement of 180° Delamination

The formulated curable liquid resin composition was applied to soda-lime glass (26 mm×76 mm; Central Glass Co., Ltd.) using a wire bar such that the applying thickness became 50 μm. The soda-lime glass applied with the curable liquid resin composition was then irradiated with ultraviolet light using a UV LED lamp having spectral peaks at 365 nm and 385 nm such that the accumulated light amounts were 840 mJ/cm² and 320 mJ/cm², respectively. The PET film (polyethylene terephthalate film) (A4360; 50 μm; Toyobo Co., Ltd.), which was pre-cut to be in the size of 20 mm×150 mm, was bonded onto the UV-irradiated soda-lime glass under bonding pressure of 0.15 MPa. After bonding, the UV light was irradiated to the PET film by using the UV LED lamp having the spectral peak of 395 nm, such that the accumulated light amount was 6000 mJ/cm² to cure the resin composition, thereby obtaining a test sample.

The peel strength of the obtained test sample was measured using a universal testing machine (Model 5965 by Instron) such that the peeling angle became 180° at the rate of 300 mm/min. The peel strength was evaluated by multiplying the peel average value of about 50 mm by 1.25 times.

The 180° peel strength at a room temperature was measured under a standard laboratory environment having at about 25 °C. The 180° peel strength at 60 °C was measured by placing the test sample in an oven previously heated to 60 °C and temperature-stabilizing for 30 minutes.

### Measurement of Storage Modulus

A release-treated PET film (Panac Corporation; NP100A) and a silicone rubber sheet (Tigers Polymer Corporation), which has a hole having a diameter of 8 mm, were sequentially laminated on a slide glass (Matsunami Glass; Slide Glass S1112). 28 μL of a curable liquid resin composition mixed was dropped into the hole of the silicone rubber, and UV light was irradiated using the UV LED lamps having spectral peaks at 405 nm and 365 nm such that the accumulated light amounts were 220 mJ/cm² and 380 mJ/cm², respectively. After the irradiation, the release-treated PET film (Panac Corporation; NP100A) and the slide glass (Matsunami Glass; Slide Glass S1112) were sequentially laminated. The UV light was irradiated from the side of the slide glass laminated by using the UV LED lamp having the spectral peak at 395 nm such that the accumulated light amount was 4000 mJ/cm², to cure the resin composition, thereby obtaining the measurement sample having a diameter of 8 mm and a thickness of 500 μm.

The obtained sample was measured for storage modulus at a measurement temperature of −50 °C to 60 °C and a measurement frequency of 1 Hz in compliance with JIS K 7244-7 using a viscoelasticity measuring device (MCR302; Anton Paar). The storage modulus at 25 °C or 60 °C was recognized based on the measurement result.

TABLE 2

| Item | Physical property | |
|---|---|---|
| Viscosity at 25 °C | 14 | mPa · s |
| 180° peel strength at 25 °C | 3.4 | kgf |
| 180° peel strength at 60 °C | 1.2 | kgf |
| Storage modulus at 25 °C | 0.073 | MPa |
| Storage modulus at 60 °C | 0.036 | MPa |

The adhesive member was formed using the resin composition which has the physical properties as shown in Table 2. Table 3 shows the applying patterns used according to the example and the manufacturing example, and Table 4 shows the curing conditions. Table 5 illustrates an applying pattern and a curing condition according to an example and a comparative example. The applying pattern of the first applying step and the second applying step when manufacturing the adhesive member, were represented in the manner of Equation 2 and Table 1 described above. In Table 3, 100% of applying amount refers to about 0.058 g/inch², and 10% of applying amount refers to about 0.0058 g/inch². The UVA and UVV values shown in Table 4 are the illuminance and accumulated light amount of ultraviolet light measured using a UV Power Puck II (Excelitas Noblelight), where UVA represents a wavelength range of 320-390 nm and UVV represents a wavelength range of 395-445 nm.

### Manner for Forming Adhesive Member

To form the adhesive members according to the example and the comparative example, DevicePrinter-CX (Microjet Corporation) equipped with KM1024i (Konica Minolta Corporation) as an inkjet device was used. A voltage, a pulse driving period, and a temperature were adjusted under a discharge condition in which the discharge speed ranged from 5.5 m/s to 6.5 m/s. After setting an applying condition such that a designated applying amount was obtained at a resolution of 360 dpi×5400 dpi, the resin composition was applied onto the soda-lime glass having a thickness of 1.1 mm, which was cleaned using an atmospheric-pressure plasma treatment device.

In this case, the applying pattern is shown in Table 3, and the curing condition is shown in Table 4. Table 5 shows the applying patterns and the curing conditions used according to the example and the comparative example. In addition, the curing condition is the same for the first light and the second light. For example, according to Example 1, it may be understood that the first applying step, a first curing step under curing condition 2, a second applying step, a second curing step under curing condition 2.

TABLE 3

| | | | | Second |
|---|---|---|---|---|
| | First applying step | | | applying step |
| Process | 1st | 2nd | 3rd | First phase |
| Printing | 0%(1)_100%(3)_0% | 0%(1)_100%(2)_0% | — | 0%(3)_100% |
| example 1 | | | | |
| Printing | 0%(1)_100%(3)_0% | 0%(1)_100%(2)_0% | 0%(1)_100%(1)_0% | 0%(3)_100% |
| example 2 | | | | |
| Printing | 0%(1)_100%(1)_0% | — | — | 0%(3)_100% |
| example 3 | | | | |
| Printing | 0%(1)_70%(4)_40% | | | 0%(1)_40%(8)_0% |
| example 4 | (8)_70% | | | |

TABLE 4

| | | UVA | | UVV |
|---|---|---|---|---|
| | Illuminance | accumulated | Illuminance | accumulated |
| | of UVA | light amount | of UVV | light amount |
| | mW/cm² | mJ/cm² | mW/cm² | mJ/cm² |
| Curing | 600 | 260 | 400 | 100 |
| condition 1 | | | | |
| Curing | 600 | 350 | 400 | 130 |
| condition 2 | | | | |
| Curing | 1000 | 480 | 0 | 0 |
| condition 3 | | | | |
| Curing | 1000 | 580 | 0 | 0 |
| condition 4 | | | | |
| Curing | 1000 | 720 | 0 | 0 |
| condition 5 | | | | |

TABLE 5

| | Printing | Curing |
|---|---|---|
| | process | process |
| Example 1 | Printing | Curing |
| | example 1 | condition 2 |
| Example 2 | Printing | Curing |
| | example 1 | condition 3 |
| Example 3 | Printing | Curing |
| | example 1 | condition 4 |
| Example 4 | Printing | Curing |
| | example 2 | condition 3 |
| Comparative | Printing | Curing |
| example 1 | example 1 | condition 1 |
| Comparative | Printing | Curing |
| example 2 | example 1 | condition 5 |
| Comparative | Printing | Curing |
| example 3 | example 3 | condition 3 |
| Comparative | Printing | Curing |
| example 4 | example 4 | condition 2 |
| Comparative | Printing | Curing |
| example 5 | example 4 | condition 4 |

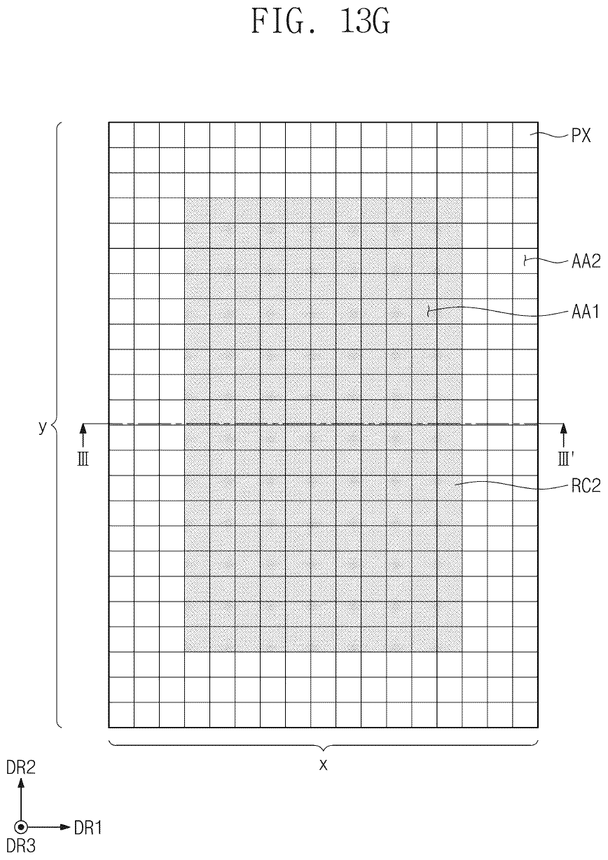

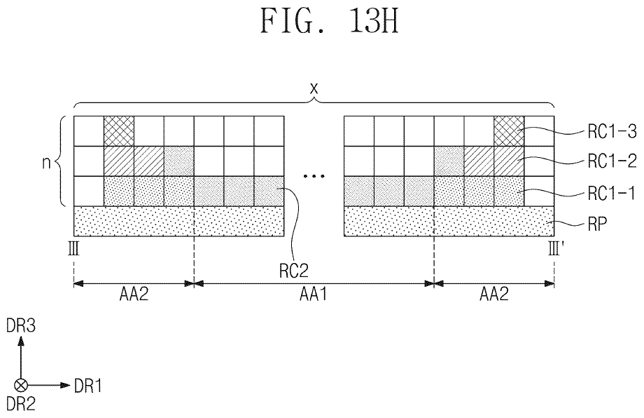

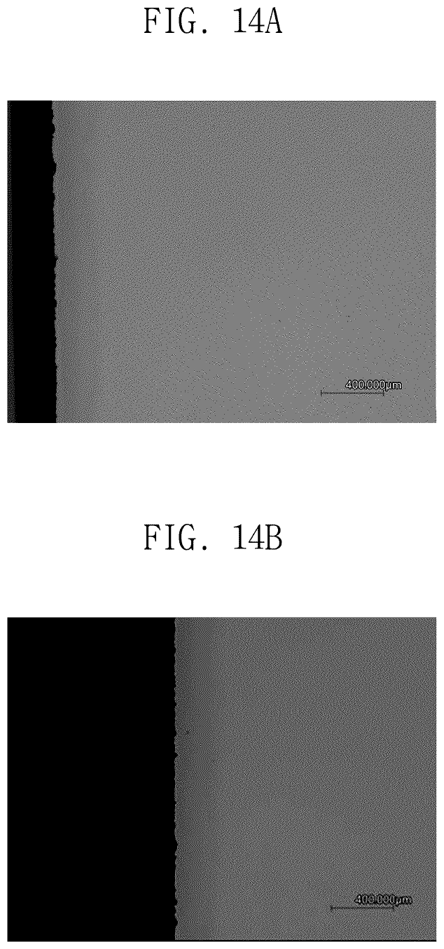

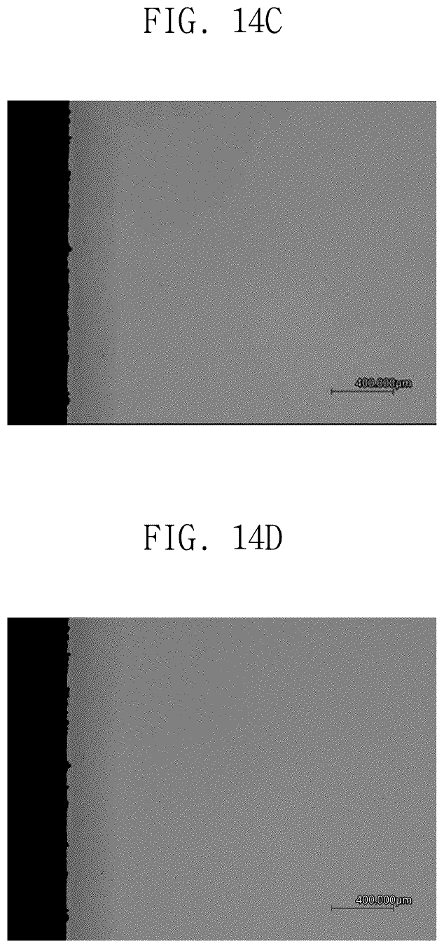

The adhesive members according to the example and the comparative example, which were formed in the above-described manner, were evaluated. The evaluating manner will be described below, and the measurement result is shown in Table 6. The measurement result of the edge gap is shown through the micro-graphs shown in FIGS. 14A-14D and 15A-15D.

### Measurement of Curing Rate

The measurement was performed using FT-IR INVENIO (Bruker Corporation) equipped with a diamond prism as an ATR prism. In the curing-rate measurement sample, the cured photo-curable resin was recovered using a spatula and was attached onto the prism, and the measurement was performed. The curing rate was calculated in Equation 1.

Curing rate (%)=(cured PI₈₁₀/cured PI₁₇₃₀)/(uncured PI₈₁₀/uncured PI₁₇₃₀)×100 Equation 1

The spectrum before curing was measured by dropping the resin composition, which is uncured, onto the prism using a pipette.

### Measurement of Edge Gap

For the sample of the adhesive-member formed according to the example and the comparative example, the glass having a thickness of 1.1 mm was roll-laminated under the pressure in a range of 0.1 MPa to 0.3 MPa, and autoclave treatment was performed for the result for 5 minutes under the conditions of 0.5 MPa and 30 °C to obtain the adhesive member sample. The obtained adhesive sample was observed through a laser microscope. For example, the distance of the voids was measured through the optical observation from the glass side, which is not applied with the resin composition, by using a laser microscope VK-X3000 (Keyence Corporation), and the distance was defined as the edge gap. The sample having the resin composition leaked on the cross-section of the glass was determined as defective bonding and was excluded from the evaluation. In addition, if (e.g., when) the edge gap was not recognized because the edge gap was less than 1 μm, “recognition fail” was described.

TABLE 6

| | Curing rate | Edge gap (μm) |
|---|---|---|
| Example 1 | 53% | Recognition fail |
| Example 2 | 70% | Recognition fail |
| Example 3 | 81% | Recognition fail |
| Example 4 | 71% | Recognition fail |
| Comparative | 48% | Bonding fail |
| example 1 | | |
| Comparative | 88% | 1245 |
| example 2 | | |
| Comparative | 70% | 114 |
| example 3 | | |
| Comparative | 93% | 526 |
| example 4 | | |
| Comparative | 97% | 843 |
| example 5 | | |

Referring to Table 6 and FIGS. 14A to 14C, the adhesive member according to one or more embodiments had the curing rate in a range of 50% to 85%, and the edge gap was not recognized because the edge gap was less than 1 μm.

Meanwhile, for the adhesive members according to Comparative example 1 and Comparative example 2, the same applying pattern was used and different curing conditions were used, when compared to the adhesive members according to Example to Example 3.

Comparative example 1 having the lower accumulated light amount showed the lower curing rate in curing to cause the leakage of the resin composition. Accordingly, Comparative example 1 was determined to be a boning fail. In addition, it may be confirmed that the adhesive member according to Comparative example 2 having the higher accumulated light amount to show the higher curing rate. It may be confirmed that the resin composition excessively cured had a roughness at a terminal portion in curing and showed a greater edge gap.

The adhesive members according to Comparative Examples 3 to 5 were different from adhesive member according to the example, in the applying pattern of the resin composition. The adhesive member according to Comparative example 3 was formed by applying the first resin composition one time, and the adhesive members according to Comparative examples 4 and 5 were formed by changing the sequence of the first applying step and the second applying step which was different from the adhesive member according to the example.

It may be confirmed that the adhesive members according to Comparative examples 3 to 5 caused delamination between the adhesive member and the substrate, which is different from the adhesive member according to the example.

FIGS. 14A to 14D illustrate images of cross-sections of an adhesive member and a substrate according to an example, which are captured using a laser microscope. FIGS. 14A to 14D correspond to Examples 1 to 4, respectively. FIGS. 15A to 15D illustrate images of cross-sections of an adhesive member and a substrate according to a comparable example, which are captured using a laser microscope. FIGS. 15A to 15D correspond to Comparative examples 2 to 5, respectively. For Comparative example 1, because the resin composition was leaked from the sample, the edge gap may not be measured.

For FIGS. 14A to 14D, the void between the adhesive member and the substrate may not be determined. For example, it may be confirmed that the edge gap approached ‘0’. In contrast, for FIGS. 15A to 15D, it may be confirmed that the edge gap between the adhesive member and the substrate was at least 100 μm. For example, it may be confirmed that the adhesive member according to the Comparative example showed the delamination.

The resin composition according to the example may have low viscosity before curing and may exhibit excellent or suitable adhesive for after curing.

Even though the adhesive member formed in the method (e.g., manner) for forming the adhesive member according to one or more embodiments or the electronic apparatus EA manufactured through the method for manufacturing the electronic apparatus according to one or more embodiments employs the resin composition exhibiting the excellent or suitable storage modulus, the excellent or suitable adhesive strength, and the lower viscosity after curing, the void may be prevented or reduced from being formed between the adhesive member and the substrate attached with the adhesive member and the delamination may be prevented or reduced from occurred at the terminal end portion.

The electronic apparatus according to one or more embodiments may have excellent or suitable adhesion reliability and structural stability.

As described above, according to one or more embodiments, in the method (e.g., manner) for forming the adhesive member and the method for manufacturing the electronic apparatus, the adhesive member, which may exhibit the higher storage modulus without the delamination at the terminal portion after curing, and the electronic apparatus including the same may be manufactured.

In the electronic apparatus according to one or more embodiments, the adhesive member exhibits the excellent or suitable elasticity without the delamination at the terminal portion of the adhesive member.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the display panel/module, the electronic apparatus, the apparatus of manufacturing thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

Although example embodiments of the present disclosure have been described for illustrative purposes, those skilled in the art will appreciate that one or more suitable modifications, and substitutions are possible, without departing from the scope and spirit of the invention as disclosed in the appended claims.

Accordingly, the technical scope of the present disclosure is not limited to the detailed description of this specification, but should be defined by the claims and equivalents thereof.

While the present disclosure has been described with reference to one or more embodiments thereof, it will be apparent to those of ordinary skill in the art that one or more suitable changes and modifications may be made thereto without departing from the spirit and scope of the present disclosure as set forth in the appended claims and equivalents thereof.

What is claimed is:

1. A method, comprising:
preparing a substrate, in which a first region and a second region around the first region are defined; and
forming an adhesive member on the substrate,
wherein the forming of the adhesive member comprises:
applying a first resin composition to the second region of the substrate;
curing the first resin composition by irradiating first light;
applying a second resin composition on a portion or an entirety of the cured first resin composition and on the first region of the substrate; and
curing the second resin composition by irradiating second light,
wherein the applying of the first resin composition is performed multiple times,
wherein the first resin composition and the second resin composition comprise a same resin composition,
wherein the resin composition is photo-cured under a condition, in which an accumulated light amount of UV light in an atmosphere is in a range of 4,000 mJ/cm² to 8,000 mJ/cm², a 180° peel strength, which is measured on a glass substrate at 25 °C, is in a range of 2 kgf/25 mm to 5 kgf/25 mm, and a 180° peel strength, which is measured on a glass substrate at 60 °C, is in a range of 0.5 kgf/25 mm to 4 kgf/25 mm,
wherein shear viscosity of the resin composition, which is measured in a JIS Z 8803 scheme at a temperature in a range of 20 °C to 30 °C, is in a range of 10 mPa·s to 20 mPa·s, and
wherein the method is a method for manufacturing an electronic apparatus.

2. The method of claim 1, wherein a curing rate of the second resin composition is in a range of 50% to 85% as calculated by Equation 1, after the second resin composition is cured,
Curing rate (%)=(cured PI₈₁₀/cured PI₁₇₃₀)/(uncured PI₈₁₀/uncured PI₁₇₃₀)×100, Equation 1
wherein, in Equation 1, PI₈₁₀ represents a peak intensity of 810 cm⁻¹ measured by Fourier Transform Infrared Spectroscopy (FT-IR), and PI₁₇₃₀ represents a peak intensity of 1730 cm⁻¹ measured by the FT-IR.

3. The method of claim 1, wherein the resin composition is applied in an inkjet printing scheme.

4. The method of claim 1, wherein the resin composition has storage modulus in a range of 0.05 MPa to 0.10 MPa, when the storage modulus is measured at 25 °C, after performing a photo-curing process under a condition in which an accumulated light amount of UV light in an atmosphere is in a range of 4,000 mJ/cm² to 6,000 m J/cm².

5. The method of claim 1, wherein the resin composition has storage modulus in a range of 0.05 MPa to 1.80 MPa, when the storage modulus is measured at 60 °C, after performing a photo-curing process under a condition in which an accumulated light amount of UV light in an atmosphere is in a range of 4,000 mJ/cm² to 6,000 mJ/cm².

6. The method of claim 1, wherein the applying of the first resin composition is performed n times, 2≤n≤5 and n being an integer,
wherein an outer peripheral portion of the first resin composition applied at an n-th phase is overlapped with an outer peripheral portion of the first resin composition applied in an (n−1)-th phase in a thickness direction, and
wherein a width of the first resin composition applied at the n-th phase is smaller than a width of the first resin composition applied in the (n−1)-th phase.

7. The method of claim 6, wherein an applying amount per unit area of the first resin composition applied at the n-th phase is less than or equal to an applying amount per unit area of the first resin composition applied at the (n−1)-th phase.

8. The method of claim 6, wherein an applying amount per unit area of the first resin composition applied at the n-th phase or at a first phase is in a range of 0.041 g/inch² to 0.076 g/inch².

9. The method of claim 1, wherein an applying amount per unit area of the second resin composition is in a range of 0.041 g/inch² to 0.076 g/inch².

10. The method of claim 1, wherein each of the first light and the second light comprises UVA,
wherein an illuminance of the UVA is in a range of 400 mW/cm² to 1,200 mW/cm², and
wherein an accumulated light amount of the UVA is in a range of 300 mJ/cm² to 700 m J/cm².

11. The method of claim 10, wherein each of the first light and the second light comprises UVV,
wherein an illuminance of the UVV is in a range of 200 mW/cm² to 600 mW/cm², and
wherein an accumulated light amount of the UVV is in a range of 120 mJ/cm² to 150 mJ/cm².

12. The method of claim 1, wherein the second region has a width in a range of 0.1 mm to 2.0 mm.

13. A method, comprising:
preparing a substrate, in which a first region and a second region around the first region are defined; and
forming an adhesive member on the substrate,
wherein the forming of the adhesive member comprises:
applying a first resin composition to the second region of the substrate;
curing the first resin composition by irradiating first light;
applying a second resin composition on a portion or an entirety of the cured first resin composition and on the first region of the substrate; and
curing the second resin composition by irradiating second light,
wherein the applying of the first resin composition is performed n times, 2≤n≤5 and n being an integer,
wherein an outer peripheral portion of the first resin composition applied at an n-th phase is overlapped with an outer peripheral portion of the first resin composition applied in an (n−1)-th phase,
wherein a width of the first resin composition applied at the n-th phase is smaller than a width of the first resin composition applied in the (n−1)-th phase,
wherein shear viscosity, which is measured in a JIS Z 8803 scheme at a temperature in a range of 20 °C to 30 °C, is in a range of 10 mPa·s to 20 mPa·s in each of the first resin composition and the second resin composition, and
wherein the method is a method for manufacturing an electronic apparatus.

14. The method of claim 13, wherein the first resin composition and the second resin composition comprise a same resin composition.

15. The method of claim 13, wherein the substrate is seated on a stage, in the preparing for the substrate, and
wherein the stage has a temperature in a range of 20 °C to 30 °C.

16. The method of claim 13, wherein the resin composition is applied in an inkjet printing scheme.

17. The method of claim 13, wherein the adhesive member has a thickness in a range of 50 μm to 300 μm.

18. An electronic apparatus, comprising:
a display module;
a window on the display module; and
an adhesive member interposed between the display module and the window,
wherein the adhesive member comprises a polymer derived from a resin composition,
wherein the resin composition is photo-cured under a condition, in which an accumulated light amount of UV light in an atmosphere is in a range of 4,000 mJ/cm² to 8,000 mJ/cm², a 180° peel strength, which is measured on a glass substrate at 25 °C, is in a range of 2 kgf/25 mm to 5 kgf/25 mm, and a 180° peel strength, which is measured on a glass substrate at 60 °C, is in a range of 0.5 kgf/25 mm to 4 kgf/25 mm,
wherein shear viscosity of the resin composition, which is measured by in a JIS Z 8803 scheme at a temperature in a range of 20 °C to 30 °C, is in a range of 10 mPa·s to 20 mPa·s,
wherein a curing rate of the resin composition is in a range of 50% to 85% as calculated by Equation 1, after the resin composition is cured, and
wherein an edge gap between the display module and the adhesive member, or between the window and the adhesive member is at most 100 μm,
Curing rate (%)=(cured PI₈₁₀/cured PI₁₇₃₀)/(uncured PI₈₁₀/uncured PI₁₇₃₀)×100 Equation 1
in Equation 1, PI₈₁₀ representing a peak intensity of 810 cm⁻¹ measured by Fourier Transform Infrared Spectroscopy (FT-IR), and PI₁₇₃₀ representing a peak intensity of 1730 cm⁻¹ measured by the FT-IR.

19. The electronic apparatus of claim 18, wherein the display module comprises:
a display panel and an input sensing unit, and
wherein the adhesive member is interposed between the input sensing unit on the display panel and the window.

20. The electronic apparatus of claim 18, further comprising:
at least one of a processor, a memory, or a power module.
